(19) United States
(12) Patent Application Publication
(10) Pub. No.: US 2025/0329992 A1
(43) Pub. Date: Oct. 23, 2025

(54) SURFACE EMITTING ELEMENT

(71) Applicant: SONY SEMICONDUCTOR SOLUTIONS CORPORATION, KANAGAWA (JP)

(72) Inventors: HIDEKAZU AOYAGI, KUMAMOTO (JP); TOSHIKAZU IJIRO, KUMAMOTO (JP)

(21) Appl. No.: 18/867,490

(22) PCT Filed: Apr. 17, 2023
(86) PCT No.: PCT/JP2023/015343

§ 371 Date: Nov. 20, 2024

(30) Foreign Application Priority Data
May 30, 2022 (JP) 2022-087524

(51) Int. Cl. H01S 5/42; H01S 5/042; H01S 5/183

(52) U.S. Cl. CPC H01S 5/423; H01S 5/04256; H01S 5/1835

(57) ABSTRACT

To provide a surface emitting element including a conduction structure that makes a second structure including a light emitting region and an electrode conductive with good conductivity and can suppress light absorption. A surface emitting element according to the present technology includes a first structure including a substrate, and a second structure provided on the first structure and including a light emitting layer including a light emitting region, in which the first structure includes a low resistance region that is a region in contact with the second structure and has lower resistance than other regions, and the low resistance region is provided at a position deviated from at least a central portion of the light emitting region in a plan view. According to the surface emitting element according to the present technology, it is possible to provide a surface emitting element including a conduction structure that makes the second structure including the light emitting region and the electrode conductive with good conductivity and that can suppress light absorption.

### TECHNICAL FIELD

The technology according to the present disclosure (hereinafter also referred to as “the present technology”) relates to a surface emitting element.

### BACKGROUND ART

Conventionally, for example, a surface emitting element capable of obtaining a surface emission output such as a surface emitting laser and a light emitting diode is known.

Among conventional surface emitting elements, there is a surface emitting element provided on a first structure including a substrate, in which a second structure including a light emitting region and an electrode are connected via a high-concentration impurity region (highly doped region) (See, for example, Patent Documents 1 and 2.).

### CITATION LIST

### Patent Document

Patent Document 1: Japanese Patent Application Laid-Open No. H5-211346
Patent Document 2: Japanese Patent Application Laid-Open No. H6-314854

### SUMMARY OF THE INVENTION

### Problems to be Solved by the Invention

However, in the conventional surface emitting element, there is room for improvement in suppressing light absorption.

Therefore, a main object of the present technology is to provide a surface emitting element including a conduction path for making a second structure including a light emitting region and an electrode conductive with good conductivity and capable of suppressing light absorption.

### Solutions to Problems

The present technology provides a surface emitting element including:
a first structure including a substrate; and
a second structure provided on the first structure and including a light emitting layer including a light emitting region,
in which the first structure includes a low resistance region that is a region in contact with the second structure and has lower resistance than other regions, and
the low resistance region is provided at a position deviated from at least a central portion of the light emitting region in a plan view.

The low resistance region may have a higher impurity concentration than the other regions.

The second structure may include a plurality of element configuration parts arranged in an in-plane direction on the first structure via an insulating region or a high resistance region, and the low resistance region may be in contact with at least one element configuration part of the plurality of element configuration parts.

The low resistance region may be in contact with at least two element configuration parts of the plurality of element configuration parts.

The plurality of element configuration parts may include at least one first element configuration part and at least one second element configuration part, a first electrode may be provided on the at least one first element configuration part, and a second electrode may be provided on the at least one second element configuration part.

The first element configuration part may include a light emitting element configuration part including the light emitting region, and the second element configuration part may include a dummy element configuration part not including the light emitting region.

The low resistance region is in contact with the second element configuration part, and at least the second element configuration part is provided with another low resistance region connecting the low resistance region and the second electrode.

The low resistance region may be in contact with the first element configuration part.

The low resistance region may not be in contact with a central portion of the first element configuration part but may be in contact with a peripheral portion.

The second electrode may be provided on the second element configuration part via an insulating film, the low resistance region may be in contact with at least the first element configuration part and a third electrode disposed between the first and second element configuration parts, and a wiring connecting the third electrode and the second electrode may be provided on at least a side surface of the second element configuration part via an insulating film.

The at least one second element configuration part may include a plurality of dummy element configuration parts including first and second dummy element configuration parts, the second electrode may be provided on the first dummy element configuration part, another second electrode may be provided on the second dummy element configuration part via an insulating film, the low resistance region may be in contact with the light emitting element configuration part and/or the first dummy element configuration part, the first dummy element configuration part may include another low resistance region connecting the low resistance region and the second electrode, and a wiring connecting the first electrode and the another second electrode may be provided along the light emitting element configuration part and the second dummy element configuration part via an insulating film.

The plurality of element configuration parts may include a plurality of light emitting element configuration parts, and the low resistance region may be in contact with at least two of the plurality of light emitting element configuration parts.

At least one of the plurality of element configuration parts may have a mesa shape.

The second structure may include a light emitting element configuration part including the light emitting region, an electrode separated from the light emitting element configuration part in an in-plane direction and/or a stacking direction may be provided in the first structure, and the low resistance region may be in contact with the light emitting element configuration part and/or the electrode.

The light emitting element configuration part may have a mesa shape, another electrode may be provided on the light emitting element configuration part, and the electrode may be disposed on the first structure to be spaced apart from the light emitting element configuration part in the in-plane direction.

The light emitting element configuration part may have a mesa shape, another electrode may be provided on the light emitting element configuration part, and the electrode may be provided on a side surface of the light emitting element configuration part on the first structure via an insulating film.

The light emitting element configuration part may have a mesa shape, another electrode may be provided on the light emitting element configuration part, the electrode may be disposed on the first structure to be spaced apart from the light emitting element configuration part in the in-plane direction, yet another electrode may be provided on a side surface of the light emitting element configuration part on a side different from a side of the electrode via an insulating film on the first structure, and a wiring connecting the another electrode and the yet another electrode may be provided along the light emitting element configuration part.

The second structure may include a reflecting mirror on a side of the substrate of the light emitting layer and/or a side opposite to the side of the substrate.

The surface emitting element may emit light to a side of the first structure.

The surface emitting element may emit light to a side of the second structure.

### BRIEF DESCRIPTION OF DRAWINGS

FIG. 1A is a plan view of a surface emitting element according to a first embodiment of the present technology, and FIG. 1B is a cross-sectional view of the surface emitting element according to the first embodiment of the present technology.

FIG. 2 is a flowchart for explaining an example of a method of manufacturing the surface emitting element according to the first embodiment of the present technology.

FIGS. 3A and 3B are a cross-sectional view and a plan view, respectively, for each step of an example of the method of manufacturing the surface emitting element according to the first embodiment of the present technology.

FIGS. 4A and 4B are a cross-sectional view and a plan view, respectively, for each step of an example of the method of manufacturing the surface emitting element according to the first embodiment of the present technology.

FIGS. 5A and 5B are a cross-sectional view and a plan view, respectively, for each step of an example of the method of manufacturing the surface emitting element according to the first embodiment of the present technology.

FIGS. 6A and 6B are a cross-sectional view and a plan view, respectively, for each step of an example of the method of manufacturing the surface emitting element according to the first embodiment of the present technology.

FIGS. 7A and 7B are a cross-sectional view and a plan view, respectively, for each step of an example of the method of manufacturing the surface emitting element according to the first embodiment of the present technology.

FIG. 8 is a cross-sectional view of a surface emitting element according to Example 1 of the first embodiment of the present technology.

FIG. 9 is a cross-sectional view of a surface emitting element according to Example 2 of the first embodiment of the present technology.

FIG. 10A is a plan view of a surface emitting element according to a second embodiment of the present technology, and FIG. 10B is a cross-sectional view of the surface emitting element according to the second embodiment of the present technology.

FIG. 11 is a cross-sectional view of a surface emitting element according to Example 1 of the second embodiment of the present technology.

FIG. 12 is a cross-sectional view of a surface emitting element according to Example 2 of the second embodiment of the present technology.

FIG. 13A is a plan view of a surface emitting element according to a third embodiment of the present technology, and FIG. 13B is a cross-sectional view of the surface emitting element according to the third embodiment of the present technology.

FIG. 14 is a cross-sectional view of a surface emitting element according to Example 1 of the third embodiment of the present technology.

FIG. 15 is a cross-sectional view of a surface emitting element according to Example 2 of the third embodiment of the present technology.

FIG. 16A is a plan view of a surface emitting element according to a fourth embodiment of the present technology, and FIG. 16B is a cross-sectional view of the surface emitting element according to the fourth embodiment of the present technology.

FIG. 17 is a cross-sectional view of a surface emitting element according to Example 1 of the fourth embodiment of the present technology.

FIG. 18 is a cross-sectional view of a surface emitting element according to Example 2 of the fourth embodiment of the present technology.

FIG. 19A is a plan view of a surface emitting element according to a fifth embodiment of the present technology, and FIG. 19B is a cross-sectional view of the surface emitting element according to the fifth embodiment of the present technology.

FIG. 20 is a cross-sectional view of a surface emitting element according to Example 1 of the fifth embodiment of the present technology.

FIG. 21 is a cross-sectional view of a surface emitting element according to Example 2 of the fifth embodiment of the present technology.

FIG. 22A is a plan view of a surface emitting element according to a sixth embodiment of the present technology, and FIG. 22B is a cross-sectional view of the surface emitting element according to the sixth embodiment of the present technology.

FIG. 23 is a cross-sectional view of a surface emitting element according to Example 1 of the sixth embodiment of the present technology.

FIG. 24 is a cross-sectional view of a surface emitting element according to Example 2 of the sixth embodiment of the present technology.

FIG. 25A is a plan view of a surface emitting element according to a seventh embodiment of the present technology, and FIG. 25B is a cross-sectional view of the surface emitting element according to the seventh embodiment of the present technology.

FIG. 26 is a cross-sectional view of a surface emitting element according to Example 1 of the seventh embodiment of the present technology.

FIG. 27 is a cross-sectional view of a surface emitting element according to Example 2 of the seventh embodiment of the present technology.

FIG. 28A is a plan view of a surface emitting element according to an eighth embodiment of the present technology, and FIG. 28B is a cross-sectional view of the surface emitting element according to the eighth embodiment of the present technology.

FIG. 29 is a cross-sectional view of a surface emitting element according to Example 1 of the eighth embodiment of the present technology.

FIG. 30 is a cross-sectional view of a surface emitting element according to Example 2 of the eighth embodiment of the present technology.

FIG. 31A is a plan view of a surface emitting element according to a ninth embodiment of the present technology, and FIG. 31B is a cross-sectional view of the surface emitting element according to the ninth embodiment of the present technology.

FIG. 32 is a cross-sectional view of a surface emitting element according to Example 1 of the ninth embodiment of the present technology.

FIG. 33 is a cross-sectional view of a surface emitting element according to Example 2 of the ninth embodiment of the present technology.

FIG. 34A is a plan view of a surface emitting element according to a tenth embodiment of the present technology, and FIG. 34B is a cross-sectional view of the surface emitting element according to the tenth embodiment of the present technology.

FIG. 35 is a cross-sectional view of a surface emitting element according to Example 1 of the tenth embodiment of the present technology.

FIG. 36 is a cross-sectional view of a surface emitting element according to Example 2 of the tenth embodiment of the present technology.

FIG. 37A is a plan view of a surface emitting element according to Modification 1 of the first embodiment of the present technology, and FIG. 37B is a cross-sectional view of the surface emitting element according to Modification 1 of the first embodiment of the present technology.

FIG. 38A is a plan view of a surface emitting element according to Modification 2 of the first embodiment of the present technology, and FIG. 38B is a cross-sectional view of the surface emitting element according to Modification 2 of the first embodiment of the present technology.

FIG. 39 is a cross-sectional view of a surface emitting element according to Modification 3 of the first embodiment of the present technology.

FIG. 40A is a cross-sectional view of a surface emitting element according to Modification 4 of the first embodiment of the present technology, and FIG. 40B is a cross-sectional view of a surface emitting element according to Modification 5 of the first embodiment of the present technology.

FIG. 41A is a cross-sectional view of a surface emitting element according to Modification 6 of the first embodiment of the present technology, and FIG. 41B is a cross-sectional view of a surface emitting element according to Modification 7 of the first embodiment of the present technology.

FIG. 42A is a plan view of a surface emitting element according to Modification 1 of the second embodiment of the present technology, and FIG. 42B is a cross-sectional view of the surface emitting element according to Modification 1 of the second embodiment of the present technology.

FIG. 43A is a plan view of a surface emitting element according to Modification 2 of the second embodiment of the present technology, and FIG. 43B is a cross-sectional view of the surface emitting element according to Modification 2 of the second embodiment of the present technology.

FIG. 44 is a cross-sectional view of a surface emitting element according to Modification 3 of the second embodiment of the present technology.

FIG. 45A is a plan view of a surface emitting element according to Modification 1 of the third embodiment of the present technology, and FIG. 45B is a cross-sectional view of the surface emitting element according to Modification 1 of the third embodiment of the present technology.

FIG. 46 is a cross-sectional view of a surface emitting element according to Modification 2 of the third embodiment of the present technology.

FIG. 47 is a cross-sectional view of a surface emitting element according to Modification 3 of the third embodiment of the present technology.

FIG. 48 is a cross-sectional view of a surface emitting element according to a modification of the fourth embodiment of the present technology.

FIG. 49 is a cross-sectional view of a surface emitting element according to a modification of the fifth embodiment of the present technology.

FIG. 50 is a diagram illustrating an application example of the surface emitting element according to the first embodiment of the present technology to a distance measurement device.

FIG. 51 is a block diagram illustrating an example of a schematic configuration of a vehicle control system.

FIG. 52 is an explanatory diagram illustrating an example of installation positions of distance measurement devices.

### MODE FOR CARRYING OUT THE INVENTION

Hereinafter, preferred embodiments of the present technology will be described in detail with reference to the accompanying drawings. Note that, in the present specification and drawings, components having substantially the same functional configuration are denoted by the same reference signs, and redundant description is omitted. The embodiments to be described below provide representative embodiments of the present technology, and the scope of the present technology is not to be narrowly interpreted according to those embodiments. In the present specification, even in a case where it is described that the surface emitting element according to the present technology exhibits a plurality of effects, the surface emitting element according to the present technology may exhibit at least one effect. The effects described in the present specification are merely examples and are not limited, and other effects may be exerted.

Furthermore, the description will be given in the following order.
0. Introduction
1. Surface emitting element according to first embodiment of present technology
2. Surface emitting element according to second embodiment of present technology
3. Surface emitting element according to third embodiment of present technology
4. Surface emitting element according to fourth embodiment of present technology
5. Surface emitting element according to fifth embodiment of present technology
6. Surface emitting element according to sixth embodiment of present technology
7. Surface emitting element according to seventh embodiment of present technology
8. Surface emitting element according to eighth embodiment of present technology
9. Surface emitting element according to ninth embodiment of present technology
10. Surface emitting element according to tenth embodiment of present technology
11. Modifications of present technology
12. Application example to electronic device
13. Example in which surface emitting element is applied to distance measurement device
14. Example in which distance measurement device is mounted on moving body

### 0. Introduction

Some conventional surface emitting elements (for example, a surface emitting laser, a light emitting diode, or the like) have a conduction structure in which a second structure including a light emitting region and an electrode are connected via a highly doped region, the second structure being provided on a first structure including a substrate (See, for example, Patent Documents 1 and 2.). However, in these surface emitting elements, since the highly doped region exists on an optical waveguide, light absorption occurs, resulting in a decrease in output.

Therefore, as a result of intensive studies, the inventors have developed the surface emitting element according to the present technology as a surface emitting element including a conduction path for conducting the second structure including the light emitting region and the electrode with high conductivity and having a conduction path capable of suppressing light absorption.

Hereinafter, some embodiments of the surface emitting element according to the present technology will be described in detail.

### 1. Surface Emitting Element According to First Embodiment of Present Technology

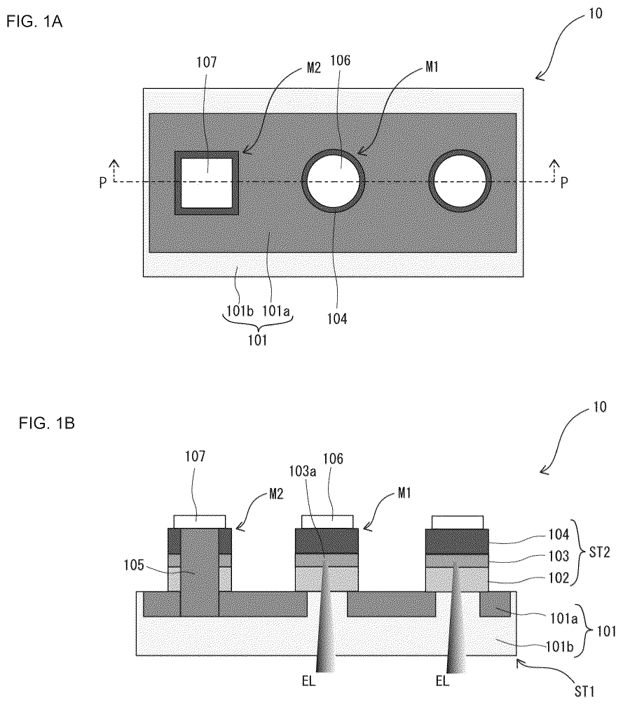

FIG. 1A is a plan view of a surface emitting element 10 according to a first embodiment of the present technology. FIG. 1B is a cross-sectional view of the surface emitting element 10 according to the first embodiment of the present technology. FIG. 1B is a cross-sectional view taken along line P-P in FIG. 1A. Hereinafter, in the cross-sectional view of FIG. 1B and the like, an upper side will be described as “upper” and a lower side will be described as “lower” as appropriate.

### Configuration of Surface Emitting Element

### Overall Configuration

As illustrated in FIGS. 1A and 1B as an example, the surface emitting element 10 according to the first embodiment of the present technology includes a first structure ST1 including a substrate 101 and a second structure ST2 provided on the first structure ST1 and including a light emitting layer 103 including a light emitting region 103a. The light emitting region 103a is a region (current injection region) into which a current is injected in the light emitting layer 103 and is a region that emits light. The surface emitting element 10 is, as an example, a backside emission type surface emitting element. That is, the surface emitting element 10 emits light to a first structure ST1 side (back surface side). Hereinafter, the direction (vertical direction) in which the first and second structures ST1 and ST2 are arranged is also referred to as a “stacking direction”.

The surface emitting element 10 is driven by a driver as an example. As an example, the driver includes a power supply and a transistor that controls on/off of energization from the power supply to the surface emitting element 10.

The second structure ST2 further includes, as an example, first and second semiconductor structures 102 and 104 sandwiching the light emitting layer 103 in the stacking direction. The first semiconductor structure 102 has a first conductivity type, and the second semiconductor structure 104 has a second conductivity type. One of the first and second conductivity types is p-type, and the other is n-type. As an example, the light emitting layer 103 includes a compound semiconductor having band gap energy smaller than those of the first and second semiconductor structures 102 and 104.

As an example, the first structure ST1 includes a substrate 101. The substrate 101 as the first structure ST1 includes, for example, a low resistance region 101a that is a region in contact with the second structure ST2 and has a lower resistance than other regions 101b. As an example, the low resistance region 101a is provided on at least a surface layer on a light emitting layer 103 side of the substrate 101. The low resistance region 101a is of the first conductivity type.

The low resistance region 101a is, for example, a high-concentration impurity region (highly doped region) having an impurity concentration (doping concentration) higher than that of the other regions 101b. The highly doped region is advantageous for reducing the resistance as a cross-sectional area perpendicular to a conduction direction is larger.

As an example, the second structure ST2 includes a plurality of element configuration parts arranged in an in-plane direction (a direction substantially orthogonal to the stacking direction) on the first structure ST1 via an insulating region or a high resistance region (for example, a gap). At least one (for example, all) of the plurality of element configuration parts has a mesa shape. That is, the plurality of element configuration parts includes a plurality of mesas M1 as a plurality of first element configuration parts and a mesa M2 as a second element configuration part.

As an example, each of the mesas M1 as the first element configuration part is a light emitting element configuration part including the light emitting region 103a. As an example, the mesa M2 as the second element configuration part is a dummy element configuration part that does not include the light emitting region 103a. As an example, the first and second mesas M1 and M2 have substantially the same height (for example, about 4 μm to 6 μm). Here, the first mesa M1 has a circular shape in plan view, but may have another shape such as an elliptical shape or a polygonal shape. The planar view shape of the second mesa M2 is a square here, but may be another shape such as a circle, an ellipse, or a polygon other than a square. The first mesa M1 is also called a “luminescent mesa”. The second mesa M2 is also called a “pedestal part” or a “dummy mesa”.

As an example, a first electrode 106 is provided on each mesa M1, and a second electrode 107 is provided on the mesa M2. That is, the first electrodes 106 and the second electrode 107 are disposed at substantially the same height. The first and second electrodes 106 and 107 are, for example, solid.

As an example, the low resistance region 101a is in contact with at least one element configuration part (for example, all element configuration parts) of the plurality of element configuration parts. Moreover, as an example, the low resistance region 101a is in contact with at least two element configuration parts (for example, all element configuration parts) among the plurality of element configuration parts. More specifically, the low resistance region 101a is in contact with at least two (for example, all) of the plurality of light emitting element configuration parts (the plurality of mesas M1) and the mesa M2 as the dummy element configuration part. The low resistance region 101a functions as a conduction path for electrically connecting the first mesas M1 and the second mesa M2 to the second electrode 107 with good conductivity.

The low resistance region 101a is provided at a position deviated from at least a central portion of the light emitting region 103a (a portion including a center of the light emitting region 103a) in plan view. More specifically, the low resistance region 101a is not in contact with the central portion of each first mesa M1 including the light emitting region 103a, but is in contact with a peripheral portion. That is, there is little or no low resistance region 101a on an optical waveguide passing through the center of the light emitting region 103a of each first mesa M1 and extending in the stacking direction.

As an example, the second mesa M2 includes another low resistance region 105 connecting the low resistance region 101a and the second electrode 107. The another low resistance region 105 functions as a conduction path that makes the low resistance region 101a and the second electrode 107 conductive with good conductivity. The another low resistance region 105 extends in the stacking direction inside the second mesa M2 as an example, and has one end (lower end) connected to the low resistance region 101a and the other end (upper end) connected to the second electrode 107. The other end (upper end) of the another low resistance region 105 is an electrode contact region. The another low resistance region 105 is of the first conductivity type.

The another low resistance region 105 is, for example, a high-concentration impurity region (highly doped region) having a higher impurity concentration (doping concentration) than other regions of the mesa M2. The highly doped region is advantageous for reducing the resistance as a cross-sectional area perpendicular to a conduction direction is larger.

### Electrode

Of the first and second electrodes 106 and 107, an electrode in contact with the p-type semiconductor is an anode electrode (p-side electrode), and an electrode in contact with the n-type semiconductor is a cathode electrode (n-side electrode). Examples of the material of the first and second electrodes 106 and 107 include a material containing at least one metal such as Au/Ni/AuGe or Au/Pt/Ti. The anode electrode is connected to an anode side of the driver, and the cathode electrode is connected to a cathode side of the driver.

### Impurity

Examples of the p-type impurity (dopant) include Zn, Mg, Be, and C. Examples of the n-type impurity (dopant) include Si, Se, and Ge. The doping concentration of each highly doped region is set to, for example, a concentration (for example, 1×18 cm⁻³ or more) at which carrier conductivity (conductivity) is higher than or equal to that of a metal used for normal wiring.

The surface emitting element 10 configured as described above has a double heterostructure in which the light emitting layer 103 is sandwiched between the first and second semiconductor structures 102 and 104 having different conductivity types in the stacking direction, and in principle, light from the light emitting layer 103 can be emitted to at least one side in the stacking direction. That is, it is possible to obtain a surface emission output.

### Mounting Method

The surface emitting element 10 is a backside emission type surface emitting element, and the first and second electrodes 106 and 107 are disposed at substantially the same height, and thus, is suitable for mounting on the driver by, for example, junction down (flip chip).

At least one of the first and second semiconductor structures 102 and 104 may include a reflecting mirror (for example, a semiconductor multilayer film reflecting mirror). For example, in a case where one of the first and second semiconductor structures 102 and 104 includes a reflecting mirror, the surface emitting element 10 can function as a high-output light emitting diode that emits light to one surface side (opposite side to a reflecting mirror side). For example, in a case where both the first and second semiconductor structures 102 and 104 include a reflecting mirror, the surface emitting element 10 can be caused to function as a surface emitting laser (vertical cavity surface emitting laser (VCSEL)).

For example, in a case where both the first and second semiconductor structures 102 and 104 do not include a reflecting mirror (for example, a semiconductor multilayer film reflecting mirror), the surface emitting element 10 is a light emitting diode that emits light to both sides. In this case, for example, it is also possible to use only the light emitted on a back surface side, but it is also possible to use the light emitted on a front surface side (driver side) as monitor light for monitoring a light amount by forming the first electrode 106 in a frame shape such as an annular shape and providing the light receiving element at an appropriate position of the driver.

### Materials of Substrate, Light Emitting Layer, and First and Second Semiconductor Structures

As the substrate 101, for example, a semiconductor substrate including an impurity semiconductor or an intrinsic semiconductor, a semi-insulating substrate, an insulating substrate, or the like can be used. As a material of the light emitting layer 103, a compound semiconductor corresponding to a desired emission wavelength can be used. In particular, in a case where the surface emitting element 10 is used as a backside emission type, the substrate 101 is required to be transparent to the emission wavelength of the light emitting layer 103. In this case, in the combination of the materials of the substrate 101 and the light emitting layer 103, for example, the material of the substrate 100 may be GaAs, InP, and Ge, and the material of the light emitting layer 103 may be GaAs-based (for example, GaAs, AlGaAs, GaInAs, GaInAsN, or the like). For example, the material of the substrate 100 may be InP, Ge, or Si, and the material of the light emitting layer 103 may be AlGaInP, for example. For example, the material of the substrate 100 may be Al₂O₃, and the material of the light emitting layer 103 may be ZnSSe-based or AlGaInN-based. The materials of the first and second semiconductor structures 102 and 104 and the light emitting layer 103 are preferably compound semiconductors lattice-matched to the substrate 101 or another substrate.

### Operation of Surface Emitting Element

Hereinafter, the operation of the surface emitting element 10 will be described. As an example, the operation of the backside emission type surface emitting element 10 in which each of the first electrodes 106 is an anode electrode (p-side electrode), the second electrode 107 is a cathode electrode (n-side electrode), the low resistance region 101a and the another low resistance region 105 are n-type with low resistance, the first semiconductor structure 102 is n-type, and the second semiconductor structure 104 is p-type will be described. When the power supply voltage of the driver is applied to the surface emitting element 10, a current from the anode side of the driver is injected into the light emitting region 103a through the first electrode 106 and the second semiconductor structure 104 of each first mesa M1 in this order. At this time, the light emitting region 103a of each first mesa M1 emits light, and light is emitted from the first mesa M1 to the back surface side. The current passing through the light emitting region 103a of each first mesa M1 flows into the low resistance region 101a (highly doped region) via the first semiconductor structure 102 of the first mesa M1. The current flowing into the low resistance region 101a flows in an in-plane direction toward the another low resistance region 105 (highly doped region) in the low resistance region 101a, and flows into the another low resistance region 105. The current flowing into the another low resistance region 105 flows toward the electrode 107 along the height direction of the second mesa M2 in the another low resistance region 105, and flows out to the cathode side of the driver via the electrode 107.

### Method of Manufacturing Surface Emitting Element

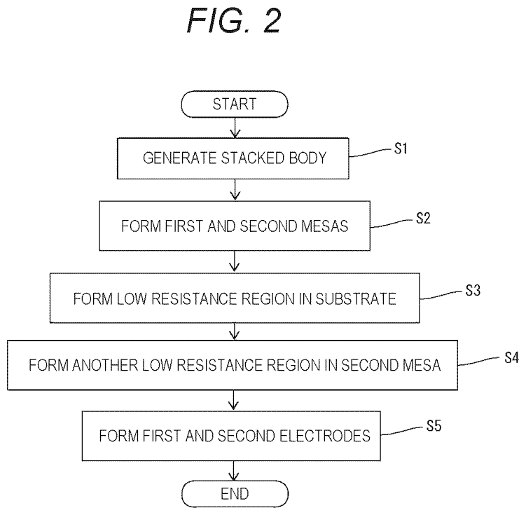

Hereinafter, a method of manufacturing the surface emitting element 10 will be described with reference to the flowchart and the like of FIG. 2. As an overall flow, first, a plurality of surface emitting elements 10 is simultaneously generated on one wafer (Hereinafter, the substrate is referred to as a “substrate 101” for convenience.) which is a base material of the substrate 101 by a semiconductor manufacturing method using a semiconductor manufacturing device. Next, the plurality of continuous integrated surface emitting elements 10 is separated from each other by dicing to obtain a chip-shaped surface emitting element 10. Here, the first and second semiconductor structures 102 and 104 and the light emitting layer 103 include a compound semiconductor lattice-matched to the material of the substrate 101.

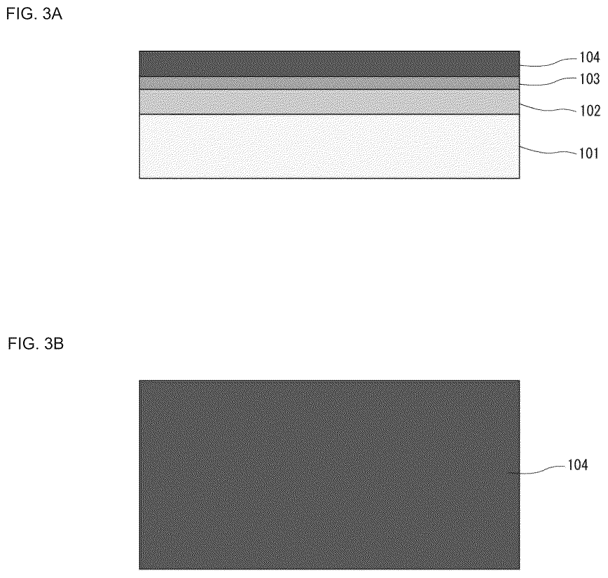

In the first step S1, a stacked body is generated (see FIGS. 3A and 3B). Specifically, for example, the first semiconductor structure 102 of the first conductivity type, the light emitting layer 103, and the second semiconductor structure 104 of the second conductivity type are stacked in this order on the substrate 101 as a growth substrate by an epitaxial crystal growth method such as a metal organic chemical vapor deposition (MOCVD) method to generate a stacked body. At this time, as raw materials of the compound semiconductor, for example, a methyl-based organometallic gas such as trimethylaluminum (TMAl), trimethylgallium (TMGa), or trimethylindium (TMIn) and an arsine (AsH₃) gas are used, as raw materials of donor impurities, for example, disilane (Si₂H₆) is used, and as raw materials of acceptor impurities, for example, carbon tetrabromide (CBr₄) is used.

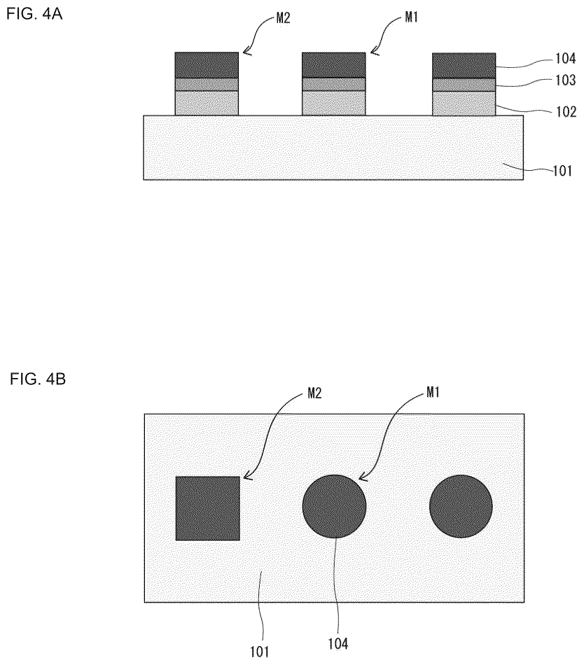

In the next step S2, the first and second mesas M1 and M2 are formed (see FIGS. 4A and 4B). Specifically, a resist pattern covering a portion where the first and second mesas M1 and M2 are to be formed is formed on the stacked body by photolithography, and the stacked body is etched by dry etching or wet etching using the resist pattern as a mask. The etching depth at this time is, for example, until the substrate 101 is exposed. Thereafter, the resist pattern is removed.

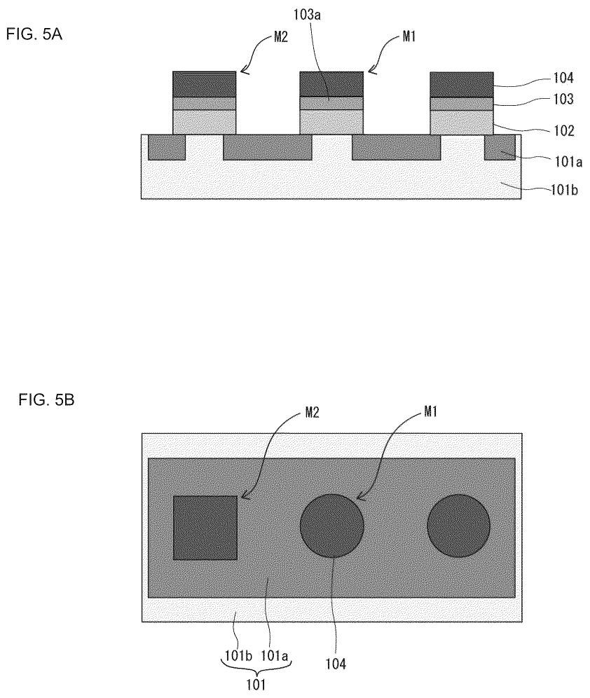

In the next step S3, a highly doped region as the low resistance region 101a is formed in the substrate 101 (see FIGS. 5A and 5B). Specifically, a resist pattern opened at a position where the low resistance region 101a is to be formed is formed on the stacked body in which the first and second mesas M1 and M2 are formed, and impurities of the first conductivity type are implanted at a high concentration using the resist pattern as a mask. At this time, it is preferable that the impurity is diffused below the first and second mesas M1 and M2 by controlling the impurity implantation direction. Thereafter, the resist pattern is removed.

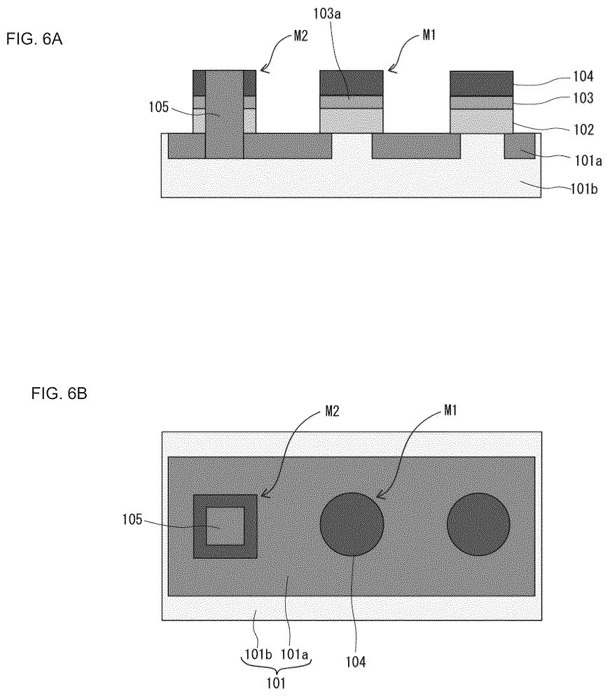

In the next step S4, a highly doped region as the another low resistance region 105 is formed at least in the second mesa M2 (see FIGS. 6A and 6B). Specifically, a resist pattern opened at the central portion of the top portion of the second mesa M2 of the stacked body on which the low resistance region 101a is formed is formed, and using the resist pattern as a mask, impurities of the first conductivity type (for example, the same impurities as the impurities of the low resistance region 101a) are implanted at a high concentration. The impurity implantation depth at this time is a depth penetrating the mesa M2, for example, a depth connected to the low resistance region 101a in the substrate 100. Thereafter, the resist pattern is removed.

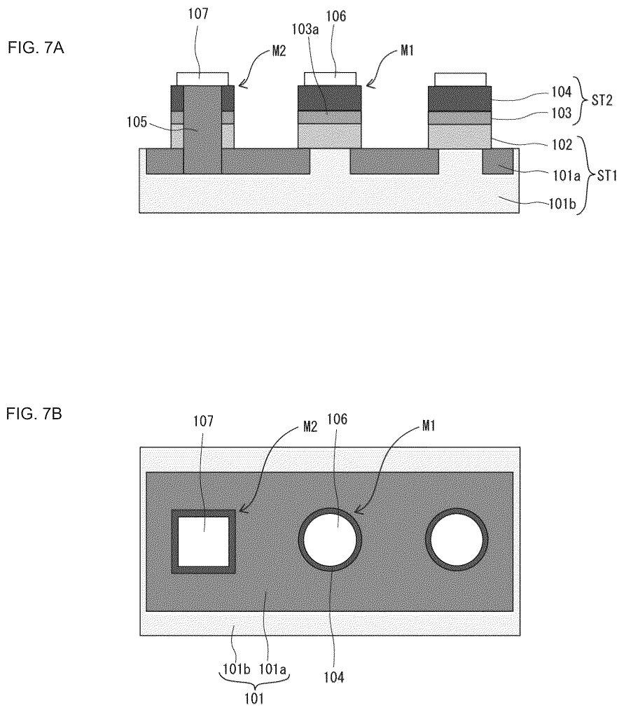

In the final step S5, the first and second electrodes 106 and 107 are formed (see FIGS. 7A and 7B). Specifically, for example, the first electrode 106 is formed on the top of the first mesa M1 by a lift-off method, and the second electrode 107 is formed on the another low resistance region 105 exposed on the top of the second mesa M2. At this time, for example, vapor deposition, sputtering, or the like is used for forming the electrode material.

Note that, in the method of manufacturing the surface emitting element 10 described above, the low resistance region 101a is formed after the first semiconductor structure 102, the light emitting layer 103, and the second semiconductor structure 104 are stacked in this order on the substrate 101, but it is not limited thereto. For example, a surface on the low resistance region 101a side of the substrate 101 (for example, a semiconductor substrate, a semi-insulating substrate, an insulating substrate, or the like) on which the low resistance region 100a is formed and a surface on the first semiconductor structure 102 side of a stacked body in which the second semiconductor structure 104, the light emitting layer 103, and the first semiconductor structure 102 are stacked in this order on another substrate (for example, a semiconductor substrate) may be aligned and joined.

### Effects of Surface Emitting Element

Hereinafter, effects of the surface emitting element 10 will be described. The surface emitting element 10 includes a first structure ST1 including a substrate 101 and a second structure ST2 provided on the first structure ST1 and including a light emitting layer 103 including a light emitting region 103a. The first structure ST1 includes a low resistance region 101a that is a region in contact with the second structure ST2 and has lower resistance than the other regions 101b. The low resistance region 101a is provided at a position deviated from at least a central portion of the light emitting region 103a in a plan view.

In this case, the second structure ST2 and the electrode (for example, the second electrode 107) can be connected via at least the low resistance region 101a, and the low resistance region 101a hardly exists or not at all on the optical waveguide passing through the center of the light emitting region 103a and extending in the stacking direction.

As a result, according to the surface emitting element 10, it is possible to provide a surface emitting element including a conduction path for making the second structure ST2 including the light emitting region 103a and the electrode (for example, the second electrode 107) conductive with good conductivity and capable of suppressing light absorption. The fact that light absorption can be suppressed leads to improvement of light output.

The low resistance region 101a has a higher impurity concentration than the other regions 101b. Thus, the low resistance region 101a can be easily formed by impurity implantation (impurity diffusion).

The second structure ST2 includes a plurality of element configuration parts arranged in the in-plane direction on the first structure ST1 via an insulating region (for example, a gap), and the low resistance region 101a is in contact with at least one element configuration part of the plurality of element configuration parts. As a result, the element configuration part and the electrode (for example, the first electrode 106 and the second electrode 107) can be electrically connected with good conductivity. That is, the at least one element configuration part and the electrode can be electrically conducted with good conductivity without using a wiring. Since the wiring is not used, defects such as disconnection (for example, step disconnection) of the wiring do not occur. The absence of the wiring leads to a reduction in manufacturing cost and an improvement in productivity because a complicated wiring forming process of stacking the metal film and the insulating film can be omitted. Since the wiring is not used, an installation space for the wiring is unnecessary, so that the element configuration parts can be arranged at high density. Since it is more difficult to form wiring on the first structure ST1 as the element configuration parts are arranged at a higher density, it is a great advantage not to use wiring in terms of improving ease of manufacturing.

The low resistance region 101a is in contact with at least two element configuration parts of the plurality of element configuration parts. Thereby, the at least two element configuration parts and the electrodes (for example, the first electrode 106 and the second electrode 107) can be electrically connected with good conductivity. That is, the at least two element configuration parts and the electrode can be electrically connected with good conductivity without using wiring.

The plurality of element configuration parts includes at least one first element configuration part (for example, two first element configuration parts) and at least one second element configuration part (for example, one second element configuration part), the first electrode 106 is provided on the at least one first element configuration part, and the second electrode 107 is provided on the at least one second element configuration part. In this case, the first and second electrodes 106 and 107 can be disposed at any height (for example, substantially the same height) on the same surface side. As a result, for example, an electrode arrangement suitable for mounting on a driver in a junction-down manner can be obtained.

The first element configuration part is a light emitting element configuration part including the light emitting region 103a, and the second element configuration part is a dummy element configuration part not including the light emitting region 103a. As a result, it is possible to construct a current injection structure including an anode electrode on one of the light emitting element configuration part and the dummy element part and including a cathode electrode on the other.

The low resistance region 101a is in contact with the dummy element configuration part as the second element configuration part, and the dummy element configuration part includes the another low resistance region 105 connecting the low resistance region 101a and the second electrode 107. As a result, the low resistance region 101a and the second electrode 107 can be conducted with good conductivity, and therefore, the light emitting element configuration part as the first element configuration part and the second electrode 107 can be conducted with better conductivity. That is, it is possible to make the light emitting element configuration part and the second electrode 107 conductive with better conductivity without using wiring. Note that the low resistance region 101a may not be in contact with the dummy element configuration part, but is preferably close to the dummy element configuration part even in that case.

The low resistance region 101a is in contact with the light emitting element configuration part as the first element configuration part. Thus, the light emitting element configuration part and the second electrode 107 can be made conductive with better conductivity. Note that, for example, in a case where the substrate 101 has conductivity, the low resistance region 101a may not be in contact with the light emitting element configuration part, but in this case, it is preferable that the low resistance region is close to the light emitting element configuration part.

The low resistance region 101a is not in contact with the central portion of the light emitting element configuration part as the first element configuration part but is in contact with the peripheral portion. Thus, the light emitting element configuration part and the second electrode 107 can be made conductive with good conductivity while suppressing light absorption.

The plurality of element configuration parts includes a plurality of light emitting element configuration parts, and the low resistance region 101a is in contact with at least two of the plurality of light emitting element configuration parts. Accordingly, the low resistance region 101a can substantially function as a common wiring common to the plurality of light emitting element parts.

At least one (for example, all) of the plurality of element configuration parts has a mesa shape. As a result, it is possible to insulate at least the upper portions of the element configuration part including the light emitting layer 103 and the second semiconductor structure 104 from each other and to impart a current confinement function and/or a light confinement function to the light emitting element part.

The second structure ST2 may include a reflecting mirror on the substrate 101 side and/or the side opposite to the substrate 101 side of the light emitting layer 103. In this case, the surface emitting element 10 can be used as a high-output light emitting diode or a surface emitting laser.

The surface emitting element 101 emits light to the first structure ST1 side (back surface side). As a result, for example, it is possible to mount on the driver by junction down.

### Example 1

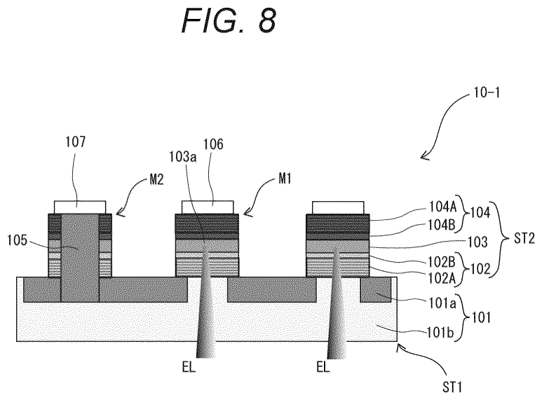

Hereinafter, a surface emitting element 10-1 according to Example 1 of the first embodiment will be described with reference to FIG. 8. As illustrated in FIG. 8, the surface emitting element 10-1 is a surface emitting laser in which both the first and second semiconductor structures 102 and 104 include a reflecting mirror.

In the surface emitting element 10-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 10-1, the second semiconductor structure 104 includes a second reflecting mirror 104A and a second cladding layer 104B stacked on each other. The second cladding layer 104B is disposed between the light emitting layer 103 and the second reflecting mirror 104A.

### Reflecting Mirror

As an example, each of the first and second reflecting mirrors 102A and 104A is a semiconductor multilayer film reflecting mirror doped with impurities, has little light absorption, and has high reflectance and conductivity. The semiconductor multilayer film reflecting mirror has a structure in which a plurality of types (for example, two types) of semiconductor layers having different refractive indexes is alternately stacked with an optical thickness of ¼ wavelength of emission wavelength. The first reflecting mirror 102A is, as an example, a semiconductor multilayer film reflecting mirror of a first conductivity type. The second reflecting mirror 104A is a semiconductor multilayer film reflecting mirror of a second conductivity type. The reflectance of the second reflecting mirror 104A is set slightly higher than that of the first reflecting mirror 102A.

Note that each of the first and second reflecting mirrors 102A and 104A may be, for example, a dielectric multilayer film reflecting mirror, a hybrid mirror in which a dielectric multilayer film reflecting mirror and a semiconductor multilayer film reflecting mirror are stacked, a hybrid mirror in which a semiconductor multilayer film reflecting mirror and a metal reflecting mirror are stacked, or a hybrid mirror in which a dielectric multilayer film reflecting mirror and a metal reflecting mirror are stacked. The first and second reflecting mirrors 102A and 104A may be different types of reflecting mirrors (mirrors). However, in a case where a mirror including a dielectric multilayer film reflecting mirror is used for at least one of the first and second reflecting mirrors 102A and 104A, the dielectric multilayer film reflecting mirror needs to be laid out so as to secure a current path (current path) from the anode electrode to the cathode electrode via the light emitting layer 103.

### Cladding Layer

The first cladding layer 102B is a compound semiconductor of the first conductivity type. The second cladding layer 104B includes a compound semiconductor of the second conductivity type. Each cladding layer is also referred to as a spacer layer.

According to the surface emitting element 10-1, it is possible to realize a backside emission type high-output surface emitting laser suitable for mounting in a junction-down manner.

### Example 2

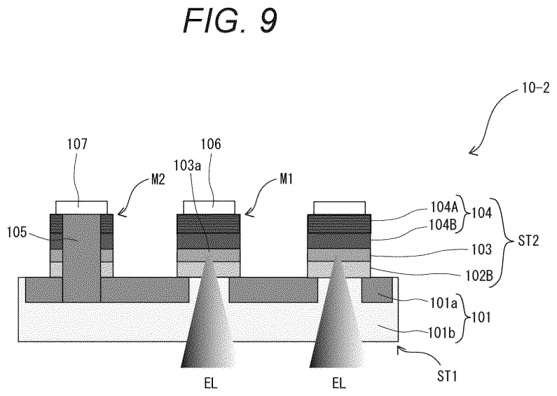

Hereinafter, a surface emitting element 10-2 according to Example 2 of the first embodiment will be described with reference to FIG. 9. As illustrated in FIG. 9, the surface emitting element 10-2 has a configuration similar to that of the surface emitting element 10-1 according to Example 1 except that it is a backside emission type light emitting diode. The surface emitting element 10-2 does not include the first reflecting mirror 102A.

According to the surface emitting element 10-2, it is possible to realize a backside emission type high-output light emitting diode suitable for mounting in a junction-down manner.

### 2. Surface Emitting Element According to Second Embodiment of Present Technology

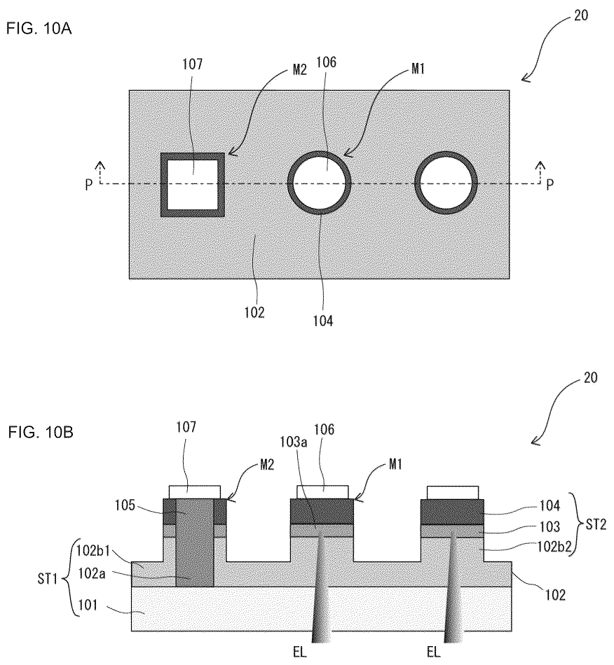

FIG. 10A is a plan view of a surface emitting element 20 according to a second embodiment of the present technology. FIG. 10B is a cross-sectional view of the surface emitting element 20 according to the second embodiment of the present technology. FIG. 10B is a cross-sectional view taken along line P-P in FIG. 10A. Hereinafter, in the cross-sectional view of FIG. 10B and the like, an upper side will be described as “upper” and a lower side will be described as “lower” as appropriate.

The surface emitting element 20 has a configuration similar to that of the surface emitting element 10 according to the first embodiment except that a low resistance region 102a is provided in a first semiconductor structure 102 immediately below a second mesa M2.

In the surface emitting element 20, the bottom surfaces of first and second mesas M1 and M2 are located in the first semiconductor structure 102.

In the surface emitting element 20, a first structure ST1 includes a substrate 101 and a lower portion 102b1 of the first semiconductor structure 102, and each of the first mesa M1 and the second mesa M2 of a second structure ST2 includes an upper portion 102b2 of the first semiconductor structure 102, a light emitting layer 103, and a second semiconductor structure 104.

In the surface emitting element 20, another low resistance region 105 provided in the second mesa M2 and the low resistance region 102a provided in the lower portion 102b1 of the first semiconductor structure 102 immediately below the second mesa M2 are connected (for example, integrated). In this case, each of light emitting element configuration parts (each of the first mesas M1) and an electrode 107 can be electrically connected with good conductivity without using a wiring. Since the wiring is not used, defects such as disconnection (for example, step disconnection) of the wiring do not occur.

The surface emitting element 20 can be manufactured by a manufacturing method according to the method of manufacturing the surface emitting element 10 according to the first embodiment.

According to the surface emitting element 20, the conductivity in the lateral direction in the first structure ST1 is inferior to that of the surface emitting element 10 according to the first embodiment, but since the formation of the low resistance region 101a can be omitted and the conduction path can be formed only by the formation of the another low resistance region 105, the manufacturing process can be simplified, and consequently, the manufacturing cost can be reduced.

### Example 1

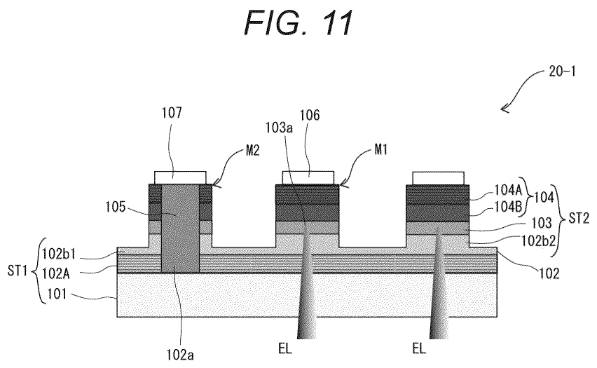

Hereinafter, a surface emitting element 20-1 according to Example 1 of the second embodiment will be described with reference to FIG. 11. As illustrated in FIG. 11, the surface emitting element 20-1 is a surface emitting laser in which both the first and second semiconductor structures 102 and 104 include a reflecting mirror.

In the surface emitting element 20-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 20-1, the second semiconductor structure 104 includes a second reflecting mirror 104A and a second cladding layer 104B stacked on each other. The second cladding layer 104B is disposed between the light emitting layer 103 and the second reflecting mirror 104A.

According to the surface emitting element 20-1, it is possible to realize a high-output and low-cost backside emission type surface emitting laser suitable for mounting in a junction-down manner.

### Example 2

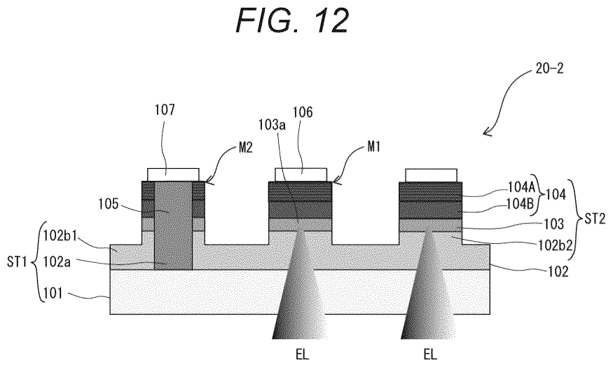

Hereinafter, a surface emitting element 20-2 according to Example 2 of the second embodiment will be described with reference to FIG. 12. As illustrated in FIG. 12, the surface emitting element 20-2 has a configuration similar to that of the surface emitting element 20-1 according to Example 1 except that it is a backside emission type light emitting diode. The surface emitting element 20-2 does not include the first reflecting mirror 102A.

According to the surface emitting element 20-2, it is possible to realize a high-output and low-cost backside emission type light emitting diode suitable for mounting in a junction-down manner.

### 3. Surface Emitting Element According to Third Embodiment of Present Technology

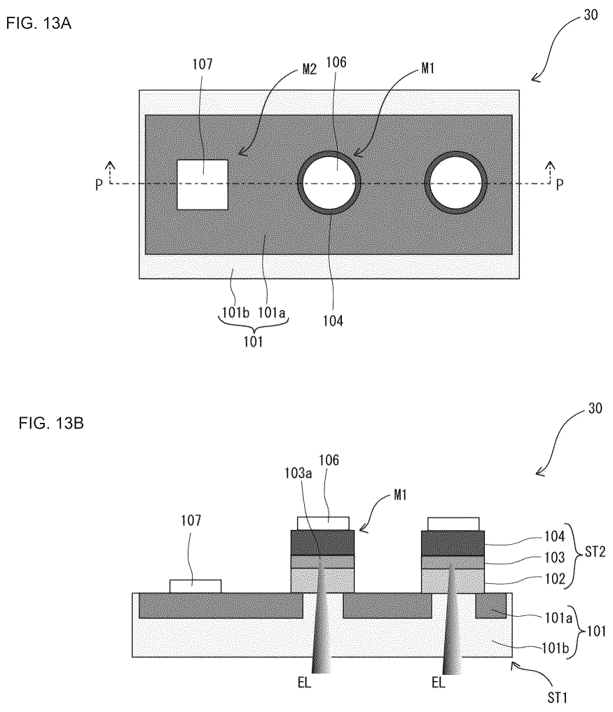

FIG. 13 is a plan view of a surface emitting element 30 according to a third embodiment of the present technology. FIG. 13A is a cross-sectional view of a surface emitting element 30 according to the third embodiment of the present technology. FIG. 13B is a cross-sectional view taken along line P-P in FIG. 13A. Hereinafter, in the cross-sectional view of FIG. 13B and the like, an upper side will be described as “upper” and a lower side will be described as “lower” as appropriate.

The surface emitting element 30 has a configuration substantially similar to that of the surface emitting element according to the first embodiment except that a second electrode 107 is directly provided on a low resistance region 101a. That is, in the surface emitting element 30, a second structure ST2 does not have a second mesa M2.

In the surface emitting element 30, the second electrode 107 is disposed on a first structure ST1 so as to be spaced apart from a first mesa M1 as a light emitting element configuration part in the in-plane direction, and the low resistance region 101a is in contact with each of the first mesa M1 and the second electrode 107. A first electrode 106 is provided on the first mesa M1.

The surface emitting element 30 can be manufactured by a manufacturing method according to the method of manufacturing the surface emitting element 10 according to the first embodiment.

According to the surface emitting element 30, for example, the first and second electrodes 106 and 107 cannot be disposed at substantially the same height as compared with the surface emitting element 10 according to the first embodiment, but since it is not necessary to form the second mesa M2 and another low resistance region 105, the manufacturing process can be simplified, and consequently, the manufacturing cost can be reduced.

### Example 1

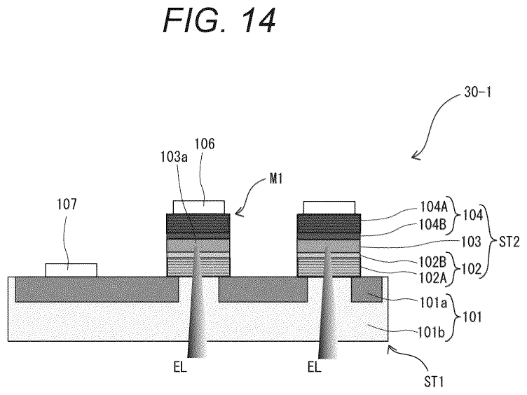

Hereinafter, a surface emitting element 30-1 according to Example 1 of the third embodiment will be described with reference to FIG. 14. As illustrated in FIG. 14, the surface emitting element 30-1 is a surface emitting laser in which both first and second semiconductor structures 102 and 104 include a reflecting mirror.

In the surface emitting element 30-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 30-1, the second semiconductor structure 104 includes a second reflecting mirror 104A and a second cladding layer 104B stacked on each other. The second cladding layer 104B is disposed between the light emitting layer 103 and the second reflecting mirror 104A.

According to the surface emitting element 30-1, a high output and low cost back surface emitting surface emitting laser can be realized.

### Example 2

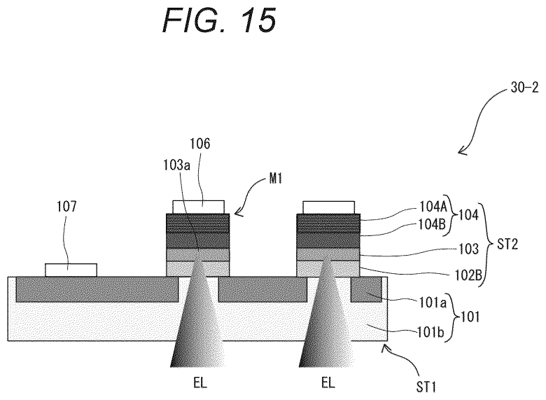

Hereinafter, a surface emitting element 30-2 according to Example 2 of the third embodiment will be described with reference to FIG. 15. As illustrated in FIG. 15, the surface emitting element 30-2 has a configuration similar to that of the surface emitting element 30-1 according to Example 1 except that it is a backside emission type light emitting diode. The surface emitting element 30-2 does not include the first reflecting mirror 102A.

According to the surface emitting element 30-2, a high output and low cost backside emission type light emitting diode can be realized.

### 4. Surface Emitting Element According to Fourth Embodiment of Present Technology

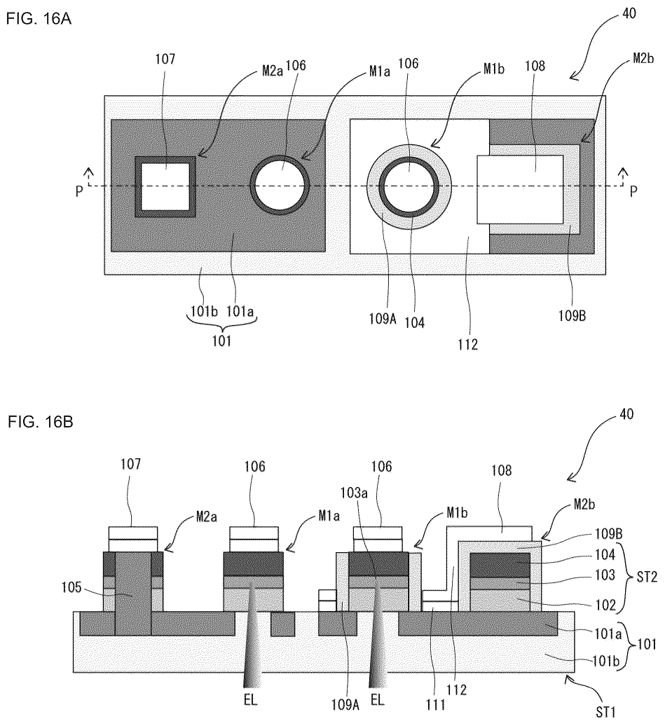

FIG. 16A is a plan view of a surface emitting element 40 according to a fourth embodiment of the present technology. FIG. 16B is a cross-sectional view of the surface emitting element 40 according to the fourth embodiment of the present technology. FIG. 16B is a cross-sectional view taken along line P-P in FIG. 16A. Hereinafter, in the cross-sectional view of FIG. 16B and the like, an upper side will be described as “upper” and a lower side will be described as “lower” as appropriate.

As illustrated in FIGS. 16A and 16B, the surface emitting element 40 has a configuration in which a part of the configuration of the surface emitting element 10 according to the first embodiment (a first element part including first and second mesas M1a and M2a provided on a substrate 101) and a second element part including first and second mesas M1b and M2b provided on the substrate 101 are combined. The first and second element parts are insulated from each other or nearly insulated from each other. As an example, the first and second element parts are laid out such that the two first mesas M1a and M1b are adjacent to each other on the substrate 101 and the two second mesas M2a and M2b sandwich the two first mesas M1a and M1b.

In the second element part, the side surface of the mesa M1b is covered with an insulating film 109A, and the side surface and the upper surface of the mesa M2b are covered with an insulating film 109B. In the second element part, a second electrode 108 is provided on the second mesa M2b (second element configuration part) via the insulating film 109B, and a low resistance region 101a is in contact with at least the first mesa M1b (first element configuration part) and a third electrode 111 as an intermediate electrode disposed between the first and second mesas M1b and M2b. The first electrode 106 is provided on the first mesa M1b. A wiring 112 connecting the third electrode 111 and the second electrode 108 is provided on at least the side surface of the second mesa M2b via the insulating film 109B. Here, the first and second electrodes 106 and 107 have a multilayer structure (for example, a two-layer structure). As the material of the wiring 112 and the second electrode 108, for example, a material containing at least one metal similar to those of the first and second electrodes 106 and 107 can be used (the similarity applies to wiring and electrodes described later).

The surface emitting element 40 can be manufactured by a manufacturing method according to the method of manufacturing the surface emitting element 10 according to the first embodiment except that a step of forming the insulating films 109A and 109B and the wiring 108 is included.

According to the surface emitting element 40, effects substantially similar to those of the surface emitting element 10 according to the first embodiment can be obtained.

### Example 1

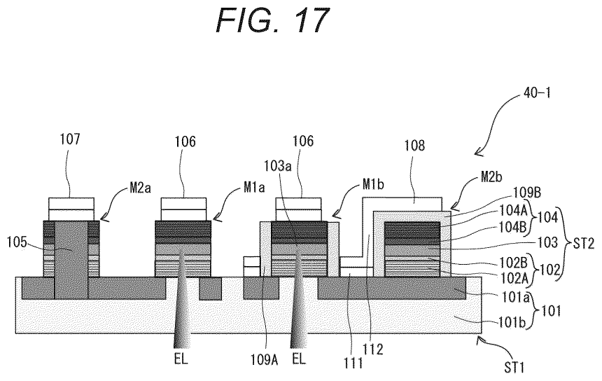

Hereinafter, a surface emitting element 40-1 according to Example 1 of the fourth embodiment will be described with reference to FIG. 17. As illustrated in FIG. 17, the surface emitting element 40-1 is a surface emitting laser in which both first and second semiconductor structures 102 and 104 include a reflecting mirror.

In the surface emitting element 40-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 40-1, the second semiconductor structure 104 includes a second reflecting mirror 104A and a second cladding layer 104B stacked on each other. The second cladding layer 104B is disposed between the light emitting layer 103 and the second reflecting mirror 104A.

According to the surface emitting element 40-1, it is possible to realize a backside emission type high-output surface emitting laser suitable for mounting in a junction-down manner.

### Example 2

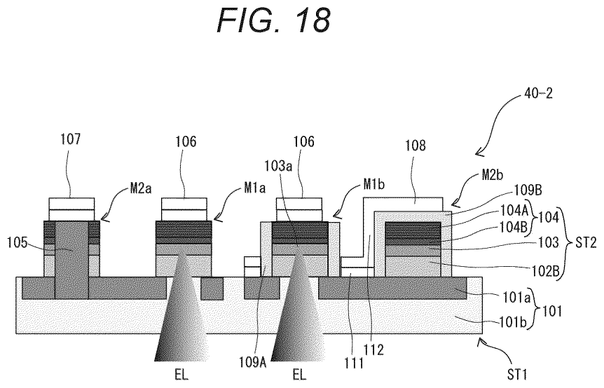

Hereinafter, a surface emitting element 40-2 according to Example 2 of the fourth embodiment will be described with reference to FIG. 18. As illustrated in FIG. 18, the surface emitting element 40-2 has a configuration similar to that of the surface emitting element 40-1 according to Example 1 except that it is a backside emission type light emitting diode. The surface emitting element 40-2 does not include the first reflecting mirror 102A.

According to the surface emitting element 40-2, it is possible to realize a backside emission type high-output light emitting diode suitable for mounting in a junction-down manner.

### 5. Surface Emitting Element According to Fifth Embodiment of Present Technology

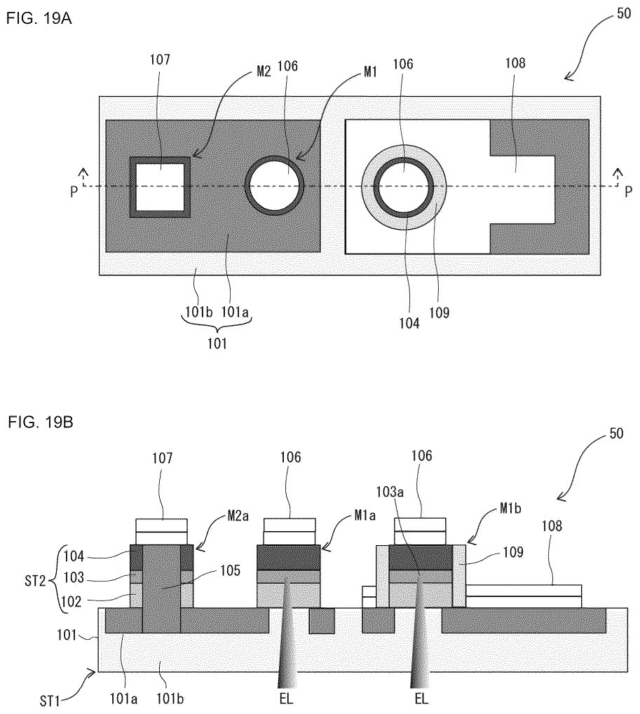

FIG. 19A is a plan view of a surface emitting element 50 according to a fifth embodiment of the present technology. FIG. 19B is a cross-sectional view of the surface emitting element 50 according to the fifth embodiment of the present technology. FIG. 19B is a cross-sectional view taken along line P-P in FIG. 19A. Hereinafter, in the cross-sectional view of FIG. 19B and the like, an upper side will be described as “upper” and a lower side will be described as “lower” as appropriate.

As illustrated in FIGS. 19A and 19B, the surface emitting element 50 has a configuration in which a part of the configuration of the surface emitting element 10 according to the first embodiment (a first element part including first and second mesas M1a and M2a provided on a substrate 101) is combined with a second element part including a first mesa M1b and a second electrode 108 provided on the substrate 101. The first and second element parts are insulated from each other or nearly insulated from each other. As an example, the first and second element parts are laid out such that the first mesa M1a is located between the first mesa M1b and the second mesa M2a on the substrate 101. Here, a first electrode 106 and the second electrodes 107 and 108 have a multilayer structure (for example, a two-layer structure).

In the second element part, the second electrode 108 is provided on the side surface of the first mesa M1b on a first structure ST1 via an insulating film 109. In the second element part, a low resistance region 101a is in contact with the first mesa M1b and the second electrode 108. The first electrode 106 is provided on the first mesa M1b.

The surface emitting element 50 can be manufactured by a manufacturing method according to the method of manufacturing the surface emitting element 10 according to the first embodiment except that a step of forming the insulating film 109 and the second electrode 108 is included.

According to the surface emitting element 50, for example, although the second electrode 108 cannot be disposed at substantially the same height as the other electrodes, effects substantially similar to those of the surface emitting element 10 according to the first embodiment can be obtained.

### Example 1

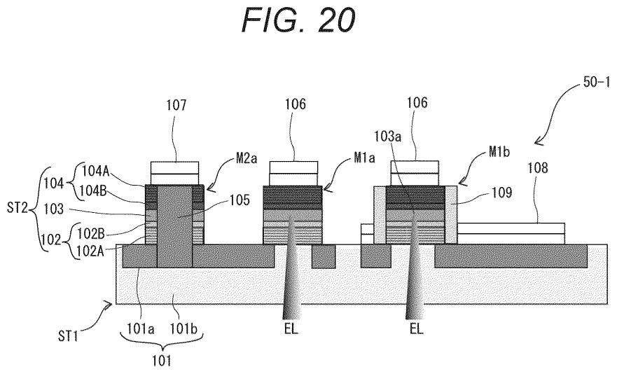

Hereinafter, a surface emitting element 50-1 according to Example 1 of the fifth embodiment will be described with reference to FIG. 20. As illustrated in FIG. 20, the surface emitting element 50-1 is a surface emitting laser in which both first and second semiconductor structures 102 and 104 include a reflecting mirror.

In the surface emitting element 50-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 50-1, the second semiconductor structure 104 includes a second reflecting mirror 104A and a second cladding layer 104B stacked on each other. The second cladding layer 104B is disposed between the light emitting layer 103 and the second reflecting mirror 104A.

According to the surface emitting element 50-1, a backside emission type high-output surface emitting laser can be realized.

### Example 2

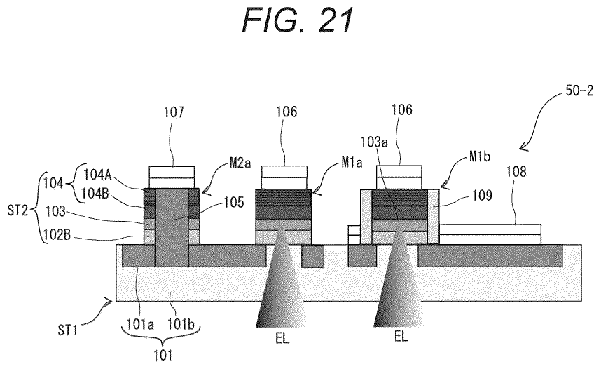

Hereinafter, a surface emitting element 50-2 according to Example 2 of the fifth embodiment will be described with reference to FIG. 21. As illustrated in FIG. 21, the surface emitting element 50-2 has a configuration similar to that of the surface emitting element 50-1 according to Example 1 except that it is a backside emission type light emitting diode. The surface emitting element 50-2 does not include the first reflecting mirror 102A.

According to the surface emitting element 50-2, a backside emission type high-output light emitting diode can be realized.

### 6. Surface Emitting Element According to Sixth Embodiment of Present Technology

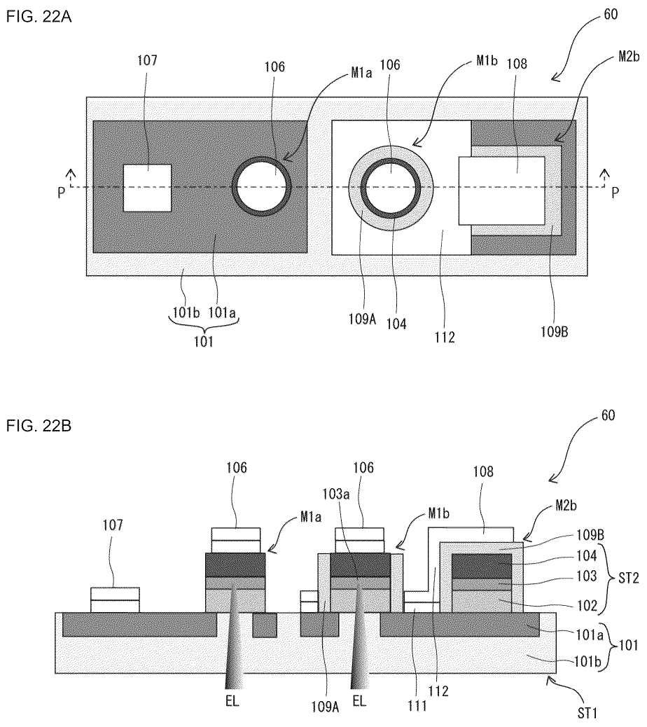

FIG. 22A is a plan view of a surface emitting element 60 according to a sixth embodiment of the present technology. FIG. 22B is a cross-sectional view of the surface emitting element 60 according to the sixth embodiment of the present technology. FIG. 22B is a cross-sectional view taken along line P-P in FIG. 22A. Hereinafter, in the cross-sectional view of FIG. 22B and the like, an upper side will be described as “upper” and a lower side will be described as “lower” as appropriate.

As illustrated in FIGS. 22A and 22B, the surface emitting element 60 has a configuration in which a part of the configuration of the surface emitting element 30 according to the third embodiment (a first element part including a first mesa M1a and a second electrode 107 provided on a substrate 101) and a part of the configuration of the surface emitting element 40 according to the fourth embodiment (a second element part including first and second mesas M1b and M2b provided on the substrate 101) are combined. The first and second element parts are insulated from each other or nearly insulated from each other. As an example, the first and second element parts are laid out such that the two first mesas M1a and M1b are adjacent to each other on the substrate 101, and the second electrode 107 and the second mesa M2b sandwich the two first mesas M1a and M1b. Here, the first and second electrodes 106 and 107 have a multilayer structure (for example, a two-layer structure).

The surface emitting element 60 can be manufactured by a manufacturing method according to the method of manufacturing the surface emitting element 30 according to the third embodiment and the surface emitting element 40 according to the fourth embodiment.

According to the surface emitting element 60, for example, although the second electrode 107 cannot be disposed at substantially the same height as the other electrodes, effects substantially similar to those of the surface emitting element 10 according to the first embodiment can be obtained.

### Example 1

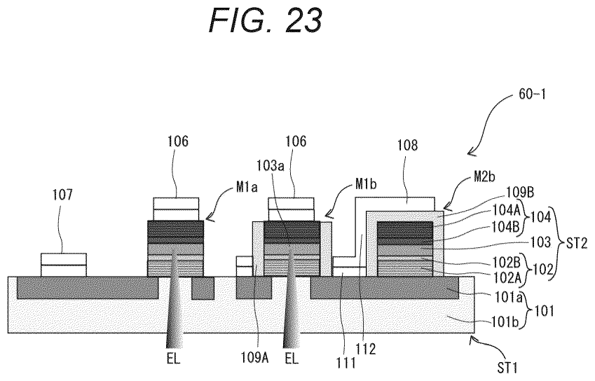

Hereinafter, a surface emitting element 60-1 according to Example 1 of the sixth embodiment will be described with reference to FIG. 23. As illustrated in FIG. 23, the surface emitting element 60-1 is a surface emitting laser in which both first and second semiconductor structures 102 and 104 include a reflecting mirror.

In the surface emitting element 60-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 60-1, the second semiconductor structure 104 includes a second reflecting mirror 104A and a second cladding layer 104B stacked on each other. The second cladding layer 104B is disposed between the light emitting layer 103 and the second reflecting mirror 104A.

According to the surface emitting element 60-1, a backside emission type high-output surface emitting laser can be realized.

### Example 2

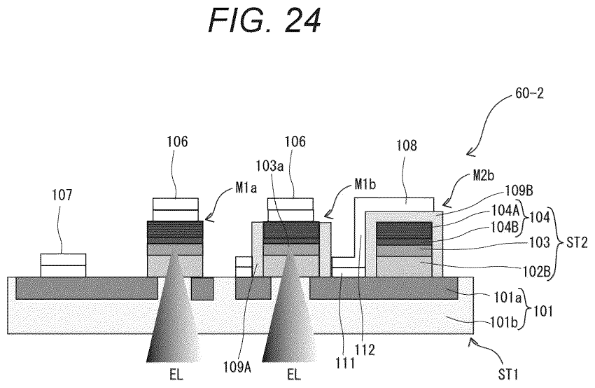

Hereinafter, a surface emitting element 60-2 according to Example 2 of the sixth embodiment will be described with reference to FIG. 24. As illustrated in FIG. 24, the surface emitting element 60-2 has a configuration similar to that of the surface emitting element 60-1 according to Example 1 except that it is a backside emission type light emitting diode. The surface emitting element 60-2 does not include the first reflecting mirror 102A.

According to the surface emitting element 60-2, a backside emission type high-output light emitting diode can be realized.

### 7. Surface Emitting Element According to Seventh Embodiment of Present Technology

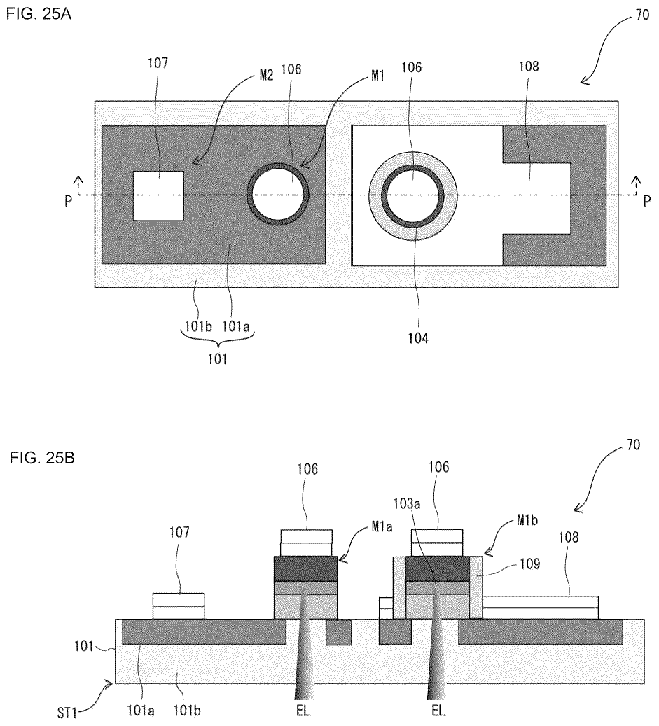

FIG. 25A is a plan view of a surface emitting element 70 according to a seventh embodiment of the present technology. FIG. 25B is a cross-sectional view of the surface emitting element 70 according to the seventh embodiment of the present technology. FIG. 25B is a cross-sectional view taken along line P-P in FIG. 25A. Hereinafter, in the cross-sectional view of FIG. 25B and the like, an upper side will be described as “upper” and a lower side will be described as “lower” as appropriate.

As illustrated in FIGS. 25A and 25B, the surface emitting element 70 has a configuration in which a part of the configuration of the surface emitting element 30 according to the third embodiment (a first element part including a first mesa M1a and a second electrode 107 provided on a substrate 101) and a part of the configuration of the surface emitting element 50 according to the fifth embodiment (a second element part including a first mesa M1b and a second electrode 108 provided on the substrate 101) are combined. The first and second element parts are insulated from each other or nearly insulated from each other. As an example, the first and second element parts are laid out such that the two first mesas M1a and M1b are adjacent to each other on the substrate 101 and the two second electrodes 107 and 108 sandwich the two first mesas M1a and M1b. Here, a first electrode 106 and the second electrodes 107 and 108 have a multilayer structure (for example, a two-layer structure).

The surface emitting element 70 can be manufactured by a manufacturing method according to the method of manufacturing the surface emitting element 30 according to the third embodiment and the surface emitting element 50 according to the fifth embodiment.

According to the surface emitting element 70, although the first electrodes 106 and the second electrodes 107 and 108 cannot be disposed at substantially the same height, effects substantially similar to those of the surface emitting element 10 according to the first embodiment can be obtained.

### Example 1

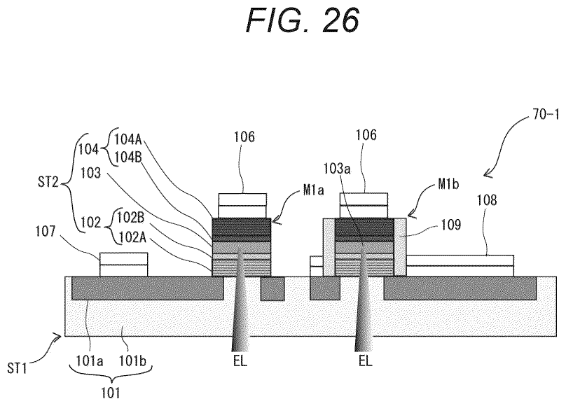

Hereinafter, a surface emitting element 70-1 according to Example 1 of the seventh embodiment will be described with reference to FIG. 26. As illustrated in FIG. 26, the surface emitting element 70-1 is a surface emitting laser in which both first and second semiconductor structures 102 and 104 include a reflecting mirror.

In the surface emitting element 70-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 70-1, the second semiconductor structure 104 includes a second reflecting mirror 104A and a second cladding layer 104B stacked on each other. The second cladding layer 104B is disposed between the light emitting layer 103 and the second reflecting mirror 104A.

According to the surface emitting element 70-1, a backside emission type high-output surface emitting laser can be realized.

### Example 2

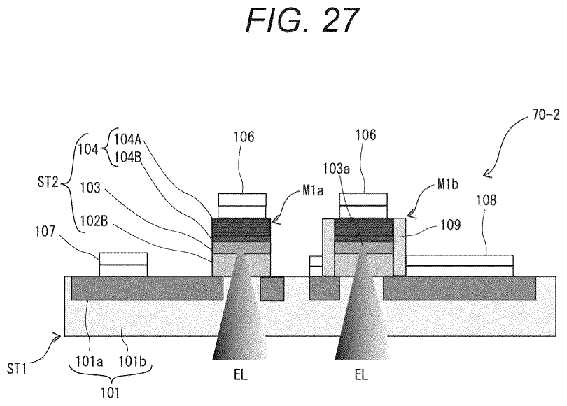

Hereinafter, a surface emitting element 70-2 according to Example 2 of the seventh embodiment will be described with reference to FIG. 27. As illustrated in FIG. 27, the surface emitting element 70-2 has a configuration similar to that of the surface emitting element 70-1 according to Example 1 except that it is a backside emission type light emitting diode. The surface emitting element 70-2 does not include the first reflecting mirror 102A.

According to the surface emitting element 70-2, a backside emission type high-output light emitting diode can be realized.

### 8. Surface Emitting Element According to Eighth Embodiment of Present Technology

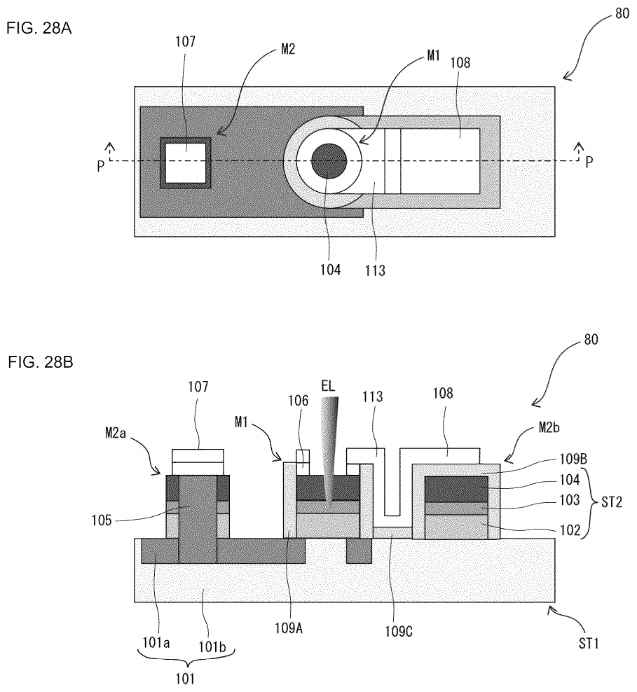

FIG. 28A is a plan view of a surface emitting element 80 according to an eighth embodiment of the present technology. FIG. 28B is a cross-sectional view of a surface emitting element 80 according to the eighth embodiment of the present technology. FIG. 28B is a cross-sectional view taken along line P-P in FIG. 28A. Hereinafter, in the cross-sectional view of FIG. 28B and the like, an upper side will be described as “upper” and a lower side will be described as “lower” as appropriate.

As illustrated in FIGS. 28A and 28B, the surface emitting element 80 is a surface emission type surface emitting element that emits light to a second structure ST2 side. In the surface emitting element 80, a first electrode 106 has a frame shape such as a ring shape, a side surface of a first mesa M1 is covered with an insulating film 109A, and a side surface and an upper surface of a second mesa M2b are covered with an insulating film 109B.

The surface emitting element 80 includes second mesas M2a and M2b as first and second dummy element components, a second electrode 107 is provided on the second mesa M2a, and another second electrode 108 is provided on the second mesa M2b via the insulating film 109B. A low resistance region 101a is in contact with the first mesa M1 and the second mesa M2a as light emitting element configuration parts. Another low resistance region 105 connecting the low resistance region 101a and the second electrode 107 is provided in at least the second mesa M2a as the first dummy element configuration part. A wiring 113 connecting the first electrode 106 and the another second electrode 108 is provided along the first mesa M1 and the second mesa M2b as the second dummy element configuration part via the insulating films 109A, 109B, and 109C.

The surface emitting element 80 can be manufactured by a manufacturing method according to the method of manufacturing the surface emitting element 10 according to the first embodiment and the surface emitting element 40 according to the fourth embodiment.

According to the surface emitting element 80, effects substantially similar to those of the surface emitting element 10 according to the first embodiment can be obtained.

### Example 1

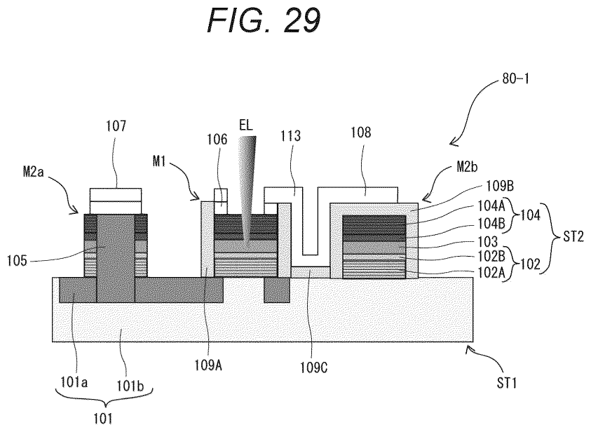

Hereinafter, a surface emitting element 80-1 according to Example 1 of the eighth embodiment will be described with reference to FIG. 29. As illustrated in FIG. 29, the surface emitting element 80-1 is a surface emission type surface emitting laser in which both first and second semiconductor structures 102 and 104 include a reflecting mirror.

In the surface emitting element 80-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 80-1, the second semiconductor structure 104 includes a second reflecting mirror 104A and a second cladding layer 104B stacked on each other. The second cladding layer 104B is disposed between the light emitting layer 103 and the second reflecting mirror 104A.

According to the surface emitting element 80-1, it is possible to realize a surface emission type high-output surface emitting laser suitable for junction-up mounting.

### Example 2

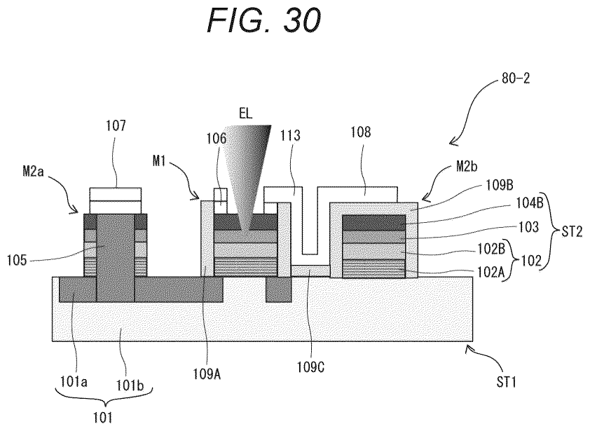

Hereinafter, a surface emitting element 80-2 according to Example 2 of the eighth embodiment will be described with reference to FIG. 30. As illustrated in FIG. 30, the surface emitting element 80-2 has a configuration similar to that of the surface emitting element 80-1 according to Example 1 except that it is a surface emission type light emitting diode. The surface emitting element 80-2 does not include the second reflecting mirror 104A.

According to the surface emitting element 80-2, it is possible to realize a surface emission type high-output light emitting diode suitable for junction-up mounting.

### 9. Surface Emitting Element According to Ninth Embodiment of Present Technology

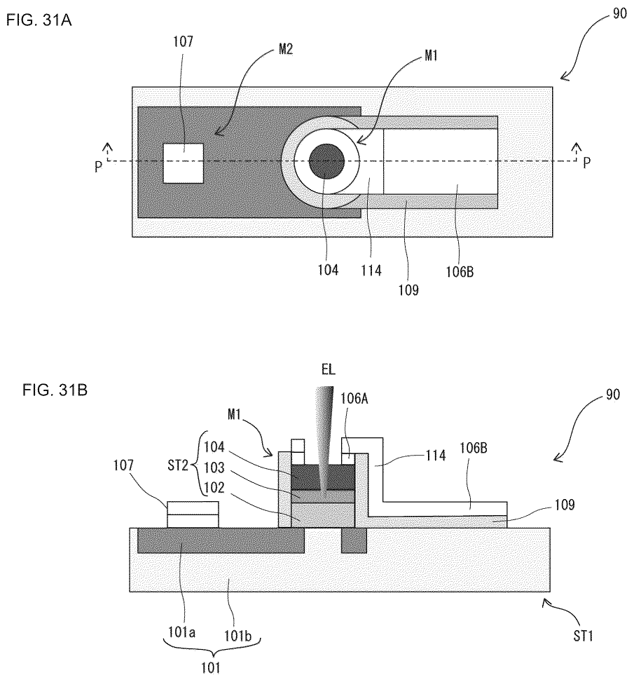

FIG. 31A is a plan view of a surface emitting element 90 according to a ninth embodiment of the present technology. FIG. 31B is a cross-sectional view of a surface emitting element 90 according to the ninth embodiment of the present technology. FIG. 31B is a cross-sectional view taken along line P-P in FIG. 31A. Hereinafter, in the cross-sectional view of FIG. 31B and the like, an upper side will be described as “upper” and a lower side will be described as “lower” as appropriate.

As illustrated in FIGS. 31A and 31B, the surface emitting element 90 is a surface emission type surface emitting element that emits light to a second structure ST2 side. In the surface emitting element 90, a first electrode 106A has a frame shape such as a ring shape, and a side surface of a first mesa M1 and a part of a substrate 101 are covered with an insulating film 109.

In the surface emitting element 90, the first electrode 106A is provided on the first mesa M1 as a light emitting element configuration part, and a second electrode 107 is disposed on a first structure ST1 so as to be spaced apart from the first mesa M1 in the in-plane direction. A first electrode 106B is provided on a side surface of the first mesa M1 on a side different from a second electrode 107 side on the first structure ST1 via the insulating film 109. A wiring 114 connecting the first electrode 106A and the first electrode 106B is provided along the first mesa M1. The first electrode 106B can be used as a connection electrode for electrically connecting to the driver.

The surface emitting element 90 can be manufactured by a manufacturing method according to the method of manufacturing the surface emitting element 10 according to the first embodiment.

According to the surface emitting element 90, for example, although the first and second electrodes 106B and 107 cannot be disposed at a desired height, it is not necessary to form the second mesa and another low resistance region 105, so that the manufacturing process can be simplified and the manufacturing cost can be reduced.

### Example 1

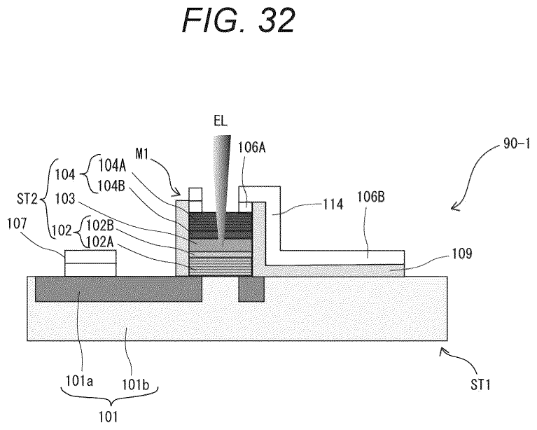

Hereinafter, a surface emitting element 90-1 according to Example 1 of the ninth embodiment will be described with reference to FIG. 32. As illustrated in FIG. 32, the surface emitting element 90-1 is a surface emission type surface emitting laser in which both first and second semiconductor structures 102 and 104 include a reflecting mirror.

In the surface emitting element 90-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 90-1, the second semiconductor structure 104 includes a second reflecting mirror 104A and a second cladding layer 104B stacked on each other. The second cladding layer 104B is disposed between the light emitting layer 103 and the second reflecting mirror 104A.

According to the surface emitting element 90-1, it is possible to realize a low-cost surface emission type high-output surface emitting laser.

### Example 2

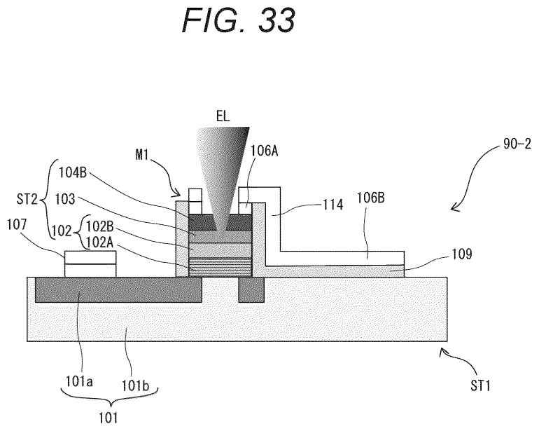

Hereinafter, a surface emitting element 90-2 according to Example 2 of the ninth embodiment will be described with reference to FIG. 33. As illustrated in FIG. 33, the surface emitting element 90-2 has a configuration similar to that of the surface emitting element 90-1 according to Example 1 except that it is a surface emission type light emitting diode. The surface emitting element 90-2 does not include the second reflecting mirror 104A.

According to the surface emitting element 90-2, it is possible to realize a low-cost surface emission type high-output light emitting diode.

### 10. Surface Emitting Element According to Tenth Embodiment of Present Technology

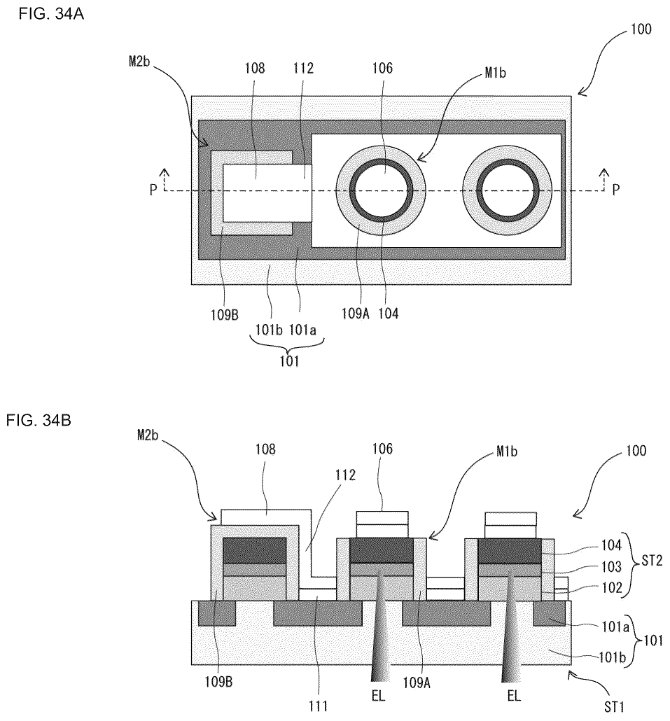

FIG. 34A is a plan view of a surface emitting element 100 according to a tenth embodiment of the present technology. FIG. 34B is a cross-sectional view of the surface emitting element 100 according to the tenth embodiment of the present technology. FIG. 34B is a sectional view taken along line P-P in FIG. 34A. Hereinafter, in the cross-sectional view of FIG. 34B and the like, an upper side will be described as “upper” and a lower side will be described as “lower” as appropriate.

As illustrated in FIGS. 34A and 34B, the surface emitting element 100 has a configuration in which a part of the surface emitting element 40 according to the fourth embodiment (a first element part including first and second mesas M1b and M2b provided on a substrate 101) and a second element part including a first mesa M1b are combined.

In the surface emitting element 100, one second mesa M2b is provided in common for two first mesas M1b adjacent to each other.

The surface emitting element 100 can be manufactured by a manufacturing method according to the method of manufacturing the surface emitting element 10 according to the fourth embodiment.

According to the surface emitting element 100, although it is necessary to form the wiring 112 between the mesas, it is possible to obtain effects substantially similar to those of the surface emitting element 10 according to the first embodiment.

### Example 1

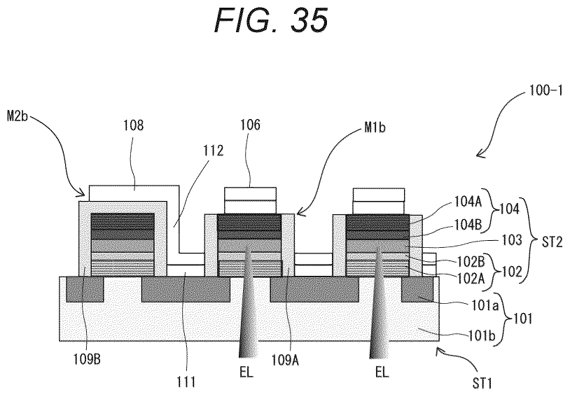

Hereinafter, a surface emitting element 100-1 according to Example 1 of the tenth embodiment will be described with reference to FIG. 35. As illustrated in FIG. 35, the surface emitting element 100-1 is a surface emission type surface emitting laser in which both first and second semiconductor structures 102 and 104 include a reflecting mirror.

In the surface emitting element 100-1, the first semiconductor structure 102 includes a first reflecting mirror 102A and a first cladding layer 102B stacked on each other. The first cladding layer 102B is disposed between the light emitting layer 103 and the first reflecting mirror 102A.

In the surface emitting element 100-1, the second semiconductor structure 104 includes a second reflecting mirror 104A and a second cladding layer 104B stacked on each other. The second cladding layer 104B is disposed between the light emitting layer 103 and the second reflecting mirror 104A.

According to the surface emitting element 100-1, it is possible to realize a backside emission type high-output surface emitting laser suitable for mounting in a junction-down manner.

### Example 2

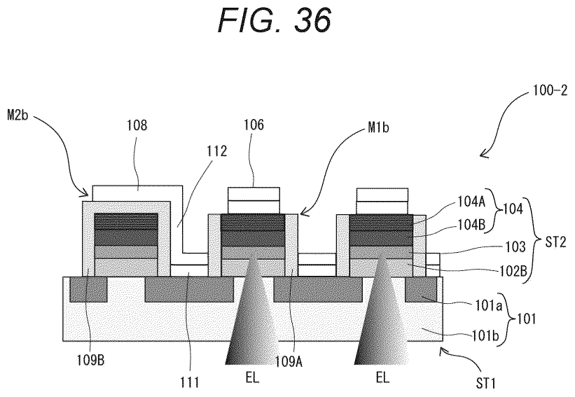

Hereinafter, a surface emitting element 100-2 according to Example 2 of the tenth embodiment will be described with reference to FIG. 36. As illustrated in FIG. 36, the surface emitting element 100-2 has the similar configuration as that of the surface emitting element 100-2 according to Example 1 except that it is a backside emission type light emitting diode. The surface emitting element 100-2 does not include the first reflecting mirror 102A.

According to the surface emitting element 100-2, it is possible to realize a backside emission type high-output light emitting diode suitable for mounting in a junction-down manner.

### 11. Modifications of Present Technology

### Surface Emitting Element According to Modification 1 of First Embodiment of Present Technology

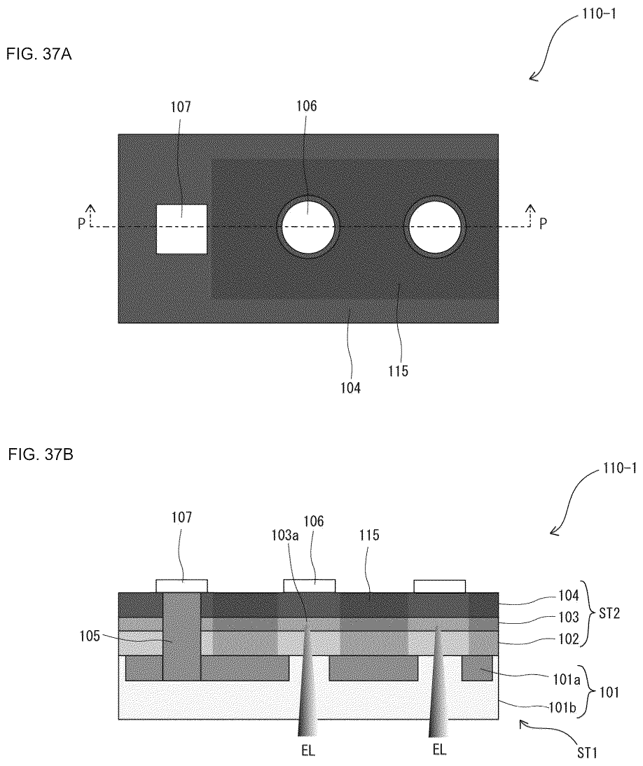

FIG. 37A is a plan view of a surface emitting element 110-1 according to Modification 1 of the first embodiment of the present technology. FIG. 37B is a cross-sectional view of the surface emitting element 110-1 according to Modification 1 of the first embodiment of the present technology. FIG. 37B is a cross-sectional view taken along line P-P in FIG. 37A. The surface emitting element 110-1 has a mesaless structure, and has a configuration similar to that of the surface emitting element 10 according to the first embodiment except that each light emitting element configuration part and the dummy element configuration part are electrically separated by an ion implantation region 115 (high resistance region).

An example of a method of manufacturing the surface emitting element 110-1 will be briefly described. Impurity diffusion is performed on the substrate 101 to form the low resistance region 101a. The second semiconductor structure 104, the light emitting layer 103, and the first semiconductor structure 102 are stacked in this order on another substrate to form a first stacked body. The ion implantation region 115 is formed by performing ion implantation from a first semiconductor structure 102 side of the first stacked body. A surface of the substrate 101 on the low resistance region 101a side and a surface of the first stacked body on the first semiconductor structure 102 side are aligned and joined to form a second stacked body. Impurity diffusion is performed from a second semiconductor structure 104 side of the second stacked body to form the another low resistance region 105.

### Surface Emitting Element According to Modification 2 of First Embodiment of Present Technology

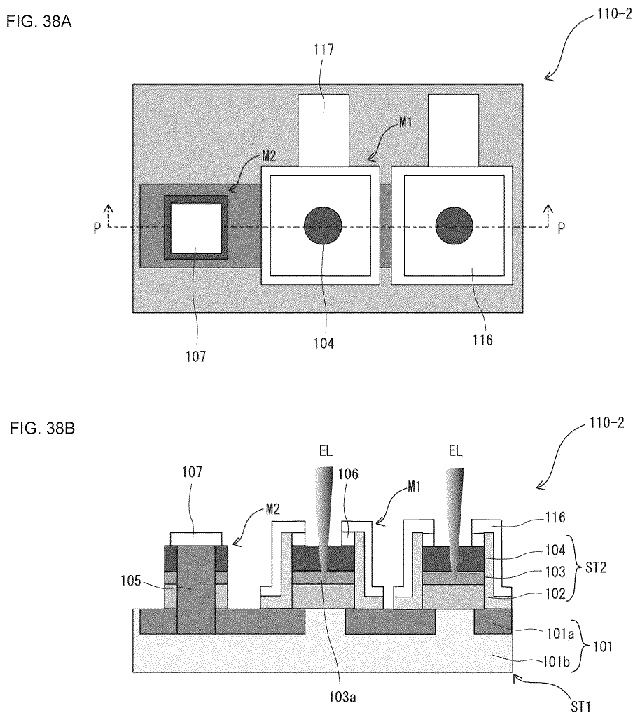

FIG. 38A is a plan view of a surface emitting element 110-2 according to Modification 2 of the first embodiment of the present technology. FIG. 38B is a cross-sectional view of the surface emitting element 110-2 according to Modification 2 of the first embodiment of the present technology. FIG. 38B is a cross-sectional view taken along line P-P in FIG. 38A. The surface emitting element 110-2 is a surface emission type, and has a configuration similar to that of the surface emitting element 10 according to the first embodiment except that a frame-shaped first electrode 106 such as a ring shape is connected to the first electrode 107 via a wiring 116.

### Surface Emitting Element According to Modification 3 of First Embodiment of Present Technology

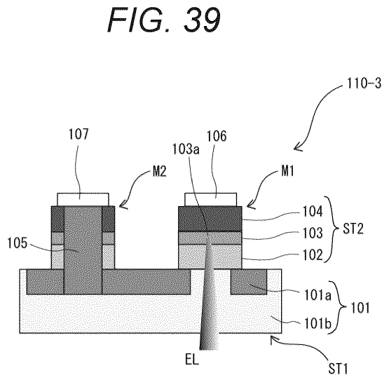

FIG. 39 is a cross-sectional view of a surface emitting element 110-3 according to Modification 3 of the first embodiment of the present technology. The surface emitting element 110-3 has a configuration substantially similar to that of the surface emitting element 10 according to the first embodiment except that the first mesa M1 is single.

### Surface Emitting Element According to Modification 4 of First Embodiment of Present Technology

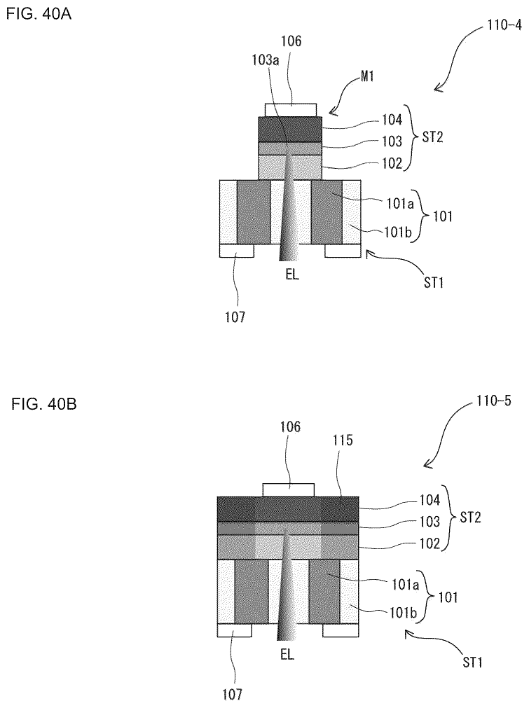

FIG. 40A is a cross-sectional view of a surface emitting element 110-4 according to Modification 4 of the first embodiment of the present technology. The surface emitting element 110-4 has a configuration substantially similar to that of the surface emitting element 10 according to the first embodiment except that the first mesa M1 is single and the second electrode 107 provided on the back surface of the substrate 101 and the first mesa M1 are connected via the low resistance region 101a.

### Surface Emitting Element According to Modification 5 of First Embodiment of Present Technology

FIG. 40B is a cross-sectional view of a surface emitting element 110-5 according to Modification 5 of the first embodiment of the present technology. The surface emitting element 110-5 has a configuration substantially similar to that of the surface emitting element 10 according to the first embodiment except that the surface emitting element 110-5 has a mesaless structure including a single light emitting element configuration part, and the second electrode 107 provided on the back surface of the substrate 101 and the light emitting element configuration part are connected via the low resistance region 101a. In the surface emitting element 110-5, an ion implantation region 115 as a current confinement region is provided in the peripheral portion of the second structure ST2 including the light emitting element configuration part in the central portion.

### Surface Emitting Element According to Modification 6 of First Embodiment of Present Technology

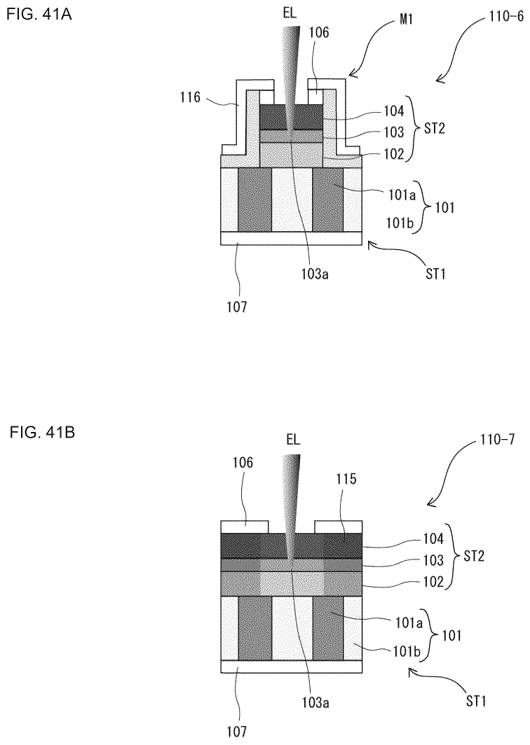

FIG. 41A is a cross-sectional view of a surface emitting element 110-6 according to Modification 6 of the first embodiment of the present technology. The surface emitting element 110-6 has substantially the similar configuration as the surface emitting element 10 according to the first embodiment except that the first mesa M1 is single and the surface emitting element 110-6 is a surface emission type surface emitting element in which the second electrode 107 provided on the back surface of the substrate 101 and the first mesa M1 are connected via the low resistance region 101a. Here, the first electrode 106 has a frame shape such as a ring shape.

### Surface Emitting Element According to Modification 7 of First Embodiment of Present Technology

FIG. 41B is a cross-sectional view of a surface emitting element 110-7 according to Modification 7 of the first embodiment of the present technology. The surface emitting element 110-7 has a configuration substantially similar to that of the surface emitting element 10 according to the first embodiment except that the surface emitting element 110-7 has a mesaless structure including a single light emitting element configuration part, and is a surface emission type surface emitting element in which the second electrode 107 provided on the back surface of the substrate 101 and the light emitting element configuration part are connected via the low resistance region 101a. In the surface emitting element 110-7, an ion implantation region 115 as a current confinement region is provided in the peripheral portion of the second structure ST2 including the light emitting element configuration part in the central portion. Here, the first electrode 106 has a frame shape such as a ring shape.

### Surface Emitting Element According to Modification 1 of Second Embodiment of Present Technology

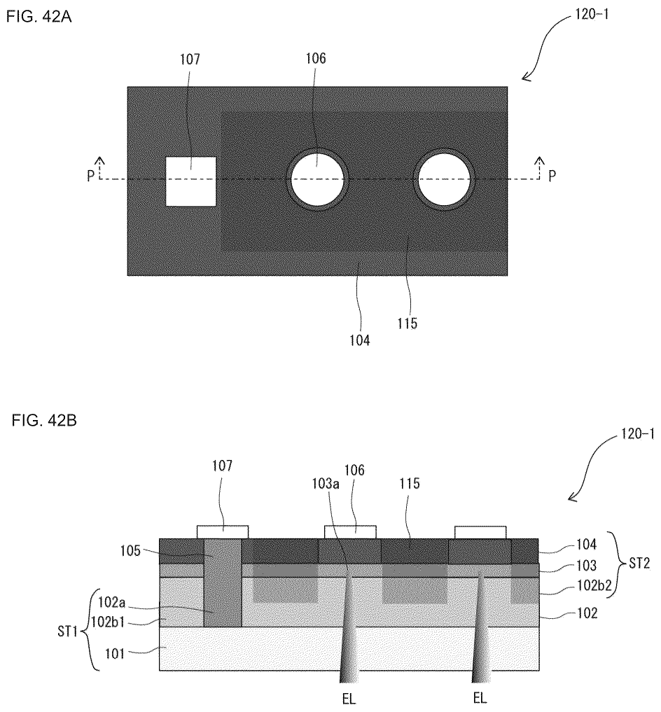

FIG. 42A is a plan view of a surface emitting element 120-1 according to Modification 1 of the second embodiment of the present technology. FIG. 42B is a cross-sectional view of the surface emitting element 120-1 according to Modification 1 of the second embodiment of the present technology. FIG. 42B is a cross-sectional view taken along line P-P in FIG. 42A. The surface emitting element 120-1 has a mesaless structure, and has a configuration similar to that of the surface emitting element 20 according to the second embodiment except that each light emitting element configuration part and the dummy element configuration part are electrically separated by the ion implantation region 115 (high resistance region).

### Surface Emitting Element According to Modification 2 of Second Embodiment of Present Technology

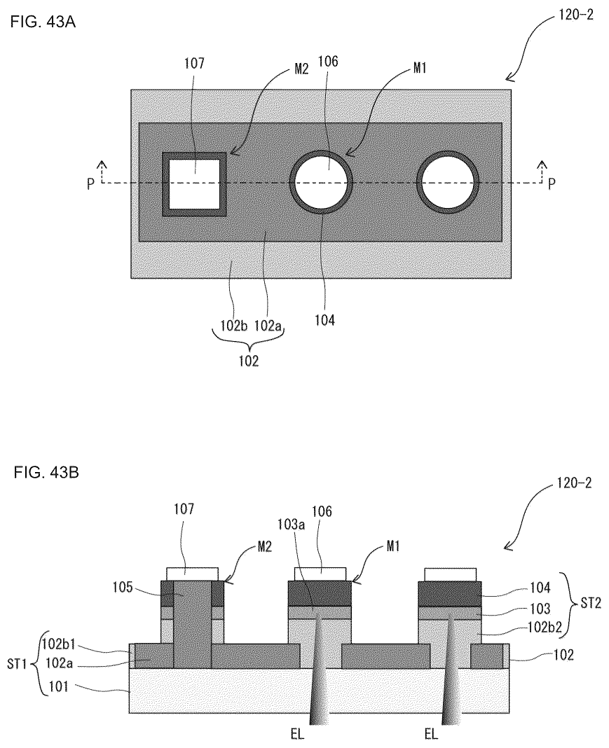

FIG. 43A is a plan view of a surface emitting element 120-2 according to Modification 2 of the second embodiment of the present technology. FIG. 43B is a cross-sectional view of the surface emitting element 120-2 according to Modification 2 of the second embodiment of the present technology. FIG. 43B is a cross-sectional view taken along line P-P in FIG. 43A. The surface emitting element 120-2 has a configuration similar to that of the surface emitting element 20 according to the second embodiment except that a low resistance region 102a in contact with each of the first mesa M1 and the second mesa M2 is provided around a lower portion 102b1 of the first semiconductor structure 102 included in the first structure ST1.

### Surface Emitting Element According to Modification 3 of Second Embodiment of Present Technology

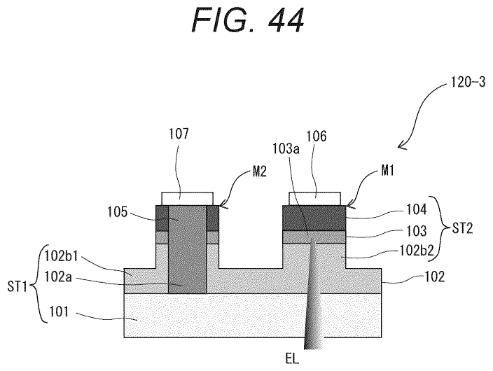

FIG. 44 is a cross-sectional view of a surface emitting element 120-3 according to Modification 3 of the second embodiment of the present technology. The surface emitting element 120-3 has a configuration substantially similar to that of the surface emitting element 20 according to the second embodiment except that the first mesa M1 is single.

### Surface Emitting Element According to Modification 1 of Third Embodiment of Present Technology

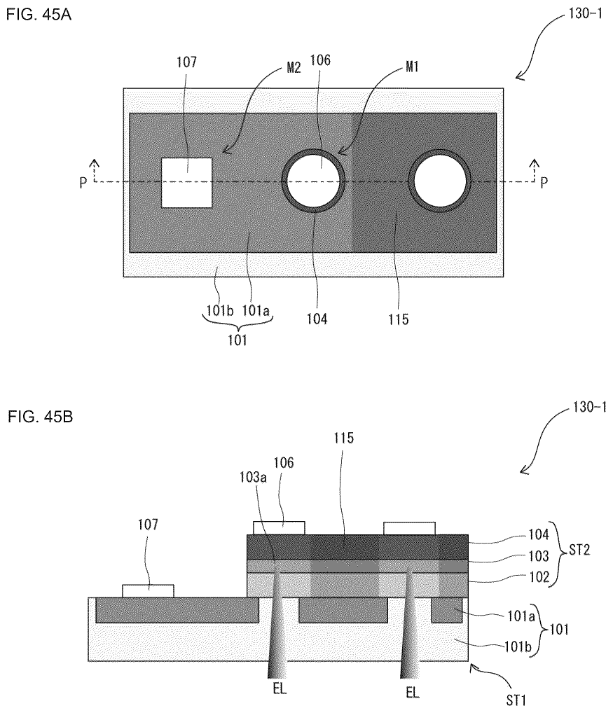

FIG. 45A is a plan view of a surface emitting element 130-1 according to Modification 1 of the third embodiment of the present technology. FIG. 45B is a cross-sectional view of the surface emitting element 130-1 according to Modification 1 of the third embodiment of the present technology. FIG. 45B is a cross-sectional view taken along line P-P in FIG. 45A. The surface emitting element 130-1 has a configuration similar to that of the surface emitting element 30 according to the third embodiment except that the surface emitting element 130-1 has a stepped mesaless structure, each light emitting element configuration part is electrically separated by the ion implantation region 115 (high resistance region), and the second electrode 107 is provided at the lower stage of the step.

### Surface Emitting Element According to Modification 2 of Third Embodiment of Present Technology

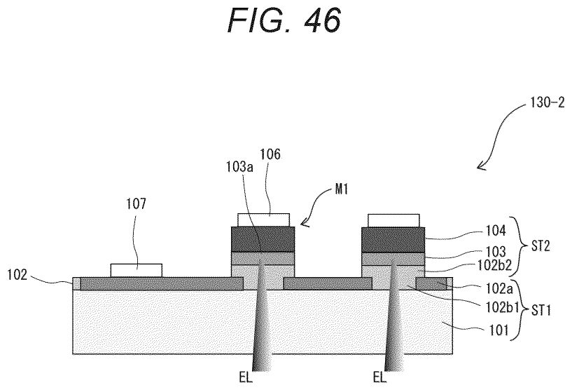

FIG. 46A is a cross-sectional view of a surface emitting element 130-2 according to Modification 2 of the third embodiment of the present technology. The surface emitting element 130-2 has a configuration similar to that of the surface emitting element 30 according to the third embodiment except that a low resistance region 102a in contact with each of the first mesas M1 and the second electrode 107 is provided around a lower portion 102b1 of the first semiconductor structure 102 included in the first structure ST1.

### Surface Emitting Element According to Modification 3 of Third Embodiment of Present Technology

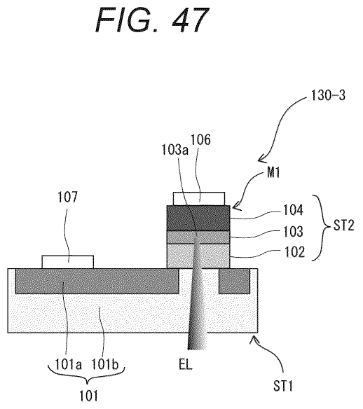

FIG. 47 is a cross-sectional view of a surface emitting element 130-3 according to Modification 3 of the third embodiment of the present technology. The surface emitting element 130-3 has a configuration substantially similar to that of the surface emitting element 30 according to the third embodiment except that the first mesa M1 is single.

### Surface Emitting Element According to Modification of Tenth Embodiment of Present Technology

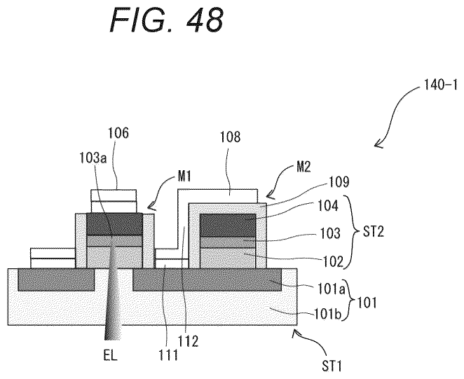

FIG. 48 is a cross-sectional view of a surface emitting element 140-1 according to a modification of the tenth embodiment of the present technology. The surface emitting element 140-1 has a configuration substantially similar to that of the surface emitting element 100 according to the tenth embodiment except that the first mesa M1 is single.

### Surface Emitting Element According to Modification of Fifth Embodiment of Present Technology

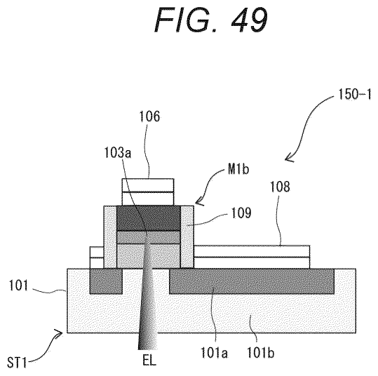

FIG. 49 is a cross-sectional view of a surface emitting element 150-1 according to a modification of the fifth embodiment of the present technology. The surface emitting element 150-1 has a configuration substantially similar to that of the surface emitting element 50 according to the fifth embodiment except that only the second element part including the first mesa M1b and the second electrode 108 is included.

In each of the above embodiments, examples, and modifications, a large number of light emitting element configuration parts may be arranged in a one-dimensional array or a two-dimensional array.

In each of the above embodiments, examples, and modifications, the element configuration parts may be electrically separated by, for example, trenches, vias, or the like.

In each of the above embodiments, examples, and modifications, a structure for confining current and/or light such as an oxidation confinement region may be provided in the light emitting element configuration part.

In each of the above embodiments, examples, and modifications, the low resistance region may not be in contact with any element configuration part.

A part of the configuration of the surface emitting element of each of the above embodiments, examples, and modifications may be combined within a range not contradictory to each other.

In each of the embodiments, examples, and modifications, the material, conductivity type, thickness, width, numerical value, shape, size, and the like of each layer constituting the surface emitting element can be appropriately changed within a range functioning as the surface emitting element.

### 12. Application Example to Electronic Device

The technology according to the present disclosure (the present technology) can be applied to various products (electronic devices). For example, the technology according to the present disclosure may be achieved in the form of a device to be mounted on a mobile body of any kind, such as an automobile, an electric vehicle, a hybrid electric vehicle, a motorcycle, a bicycle, a personal mobility, an airplane, a drone, a vessel, or a robot.

The surface emitting element according to the present technology can also be applied as, for example, a light source of a device (for example, a printer, a copier, a projector, a head-mounted display, a head-up display, or the like) that forms or displays an image by light.

### 13. Example in Which Surface Emitting Element is Applied to Distance Measurement Device

Hereinafter, an application example of the surface emitting element 10 according to the first embodiment will be described.

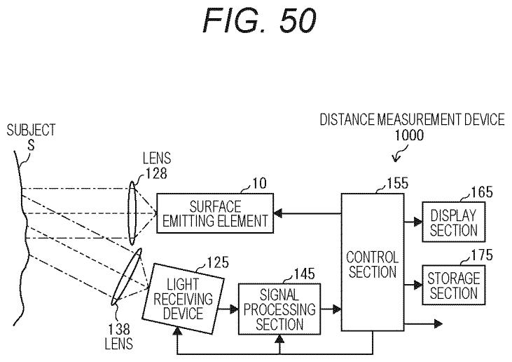

FIG. 50 illustrates an example of a schematic configuration of a distance measurement device 1000 (ranging device) including a surface emitting element 10 as an example of an electronic device according to the present technology. The distance measurement device 1000 measures a distance to a subject S by a time of flight (TOF) method. The distance measurement device 1000 includes the surface emitting element 10. The distance measurement device 1000 includes, for example, the surface emitting element 10, a light receiving device 125, lenses 128 and 138, a signal processing section 145, a control section 155, a display section 165, and a storage section 175.

The light receiving device 125 receives the light emitted from the surface emitting element 10 and reflected by the subject S (object). That is, the light receiving device 125 detects the light reflected by the subject S. The lens 128 is a lens for collimating the light emitted from the surface emitting element 10, and is, for example, a collimating lens. The lens 138 is a lens for collecting light reflected by the subject S and guiding the light to the light receiving device 125, and is, for example, a condenser lens.

The signal processing section 145 is a circuit for generating a signal corresponding to a difference between a signal input from the light receiving device 125 and a reference signal input from the control section 155. The control section 155 includes, for example, a time to digital converter (TDC). The reference signal may be a signal input from the control section 155, or may be an output signal of a detection section that directly detects the output of the surface emitting element 10. The control section 155 is, for example, a processor that controls the surface emitting element 10, the light receiving device 125, the signal processing section 145, the display section 165, and the storage section 175. The control section 155 is a circuit that measures the distance to the subject S on the basis of the signal generated by the signal processing section 145. The control section 155 generates a video signal for displaying information on the distance to the subject S, and outputs the video signal to the display section 165. The display section 165 displays information on the distance to the subject S on the basis of the video signal input from the control section 155. The control section 155 stores information on the distance to the subject S in the storage section 175.

In the present application example, any one of the surface emitting elements 10-1, 10-2, 20, 20-1, 20-2, 30, 30-1, 30-2, 40, 40-1, 40-2, 50, 50-1, 50-2, 60, 60-1, 60-2, 70, 70-1, 70-2, 80, 80-1, 80-2, 90, 90-1, 90-2, 100, 100-1, 100-2, 110-1 to 110-7, 120-1 to 120-3, 130-1 to 130-3, 140-1, and 150-1 can be applied to the distance measurement device 1000 instead of the surface emitting element 10.

### 14. Example in Which Distance Measurement Device is Mounted on Moving Body

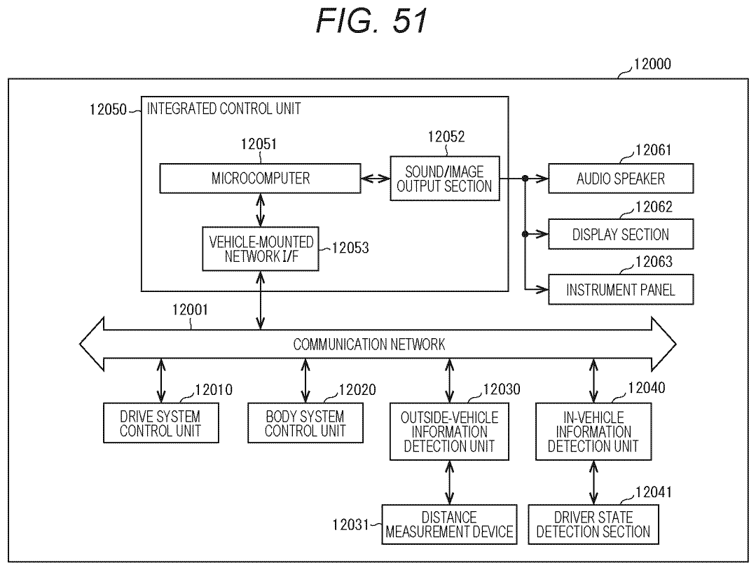

FIG. 51 is a block diagram illustrating a schematic configuration example of a vehicle control system that is an example of a moving body control system to which the technology according to the present disclosure can be applied.

The vehicle control system 12000 includes a plurality of electronic control units connected to each other via a communication network 12001. In the example illustrated in FIG. 51, the vehicle control system 12000 includes a drive system control unit 12010, a body system control unit 12020, an outside-vehicle information detection unit 12030, an in-vehicle information detection unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The drive system control unit 12010 controls the operation of devices related to the drive system of the vehicle in accordance with various programs. For example, the drive system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various lamps such as a headlamp, a back lamp, a brake lamp, a turn indicator, or a fog lamp. In this case, a radio wave transmitted from a portable device that substitutes for a key or signals of various switches may be input to the body system control unit 12020. The body system control unit 12020 receives these input radio waves or signals, and controls a door lock device, the power window device, the lamps, or the like of the vehicle.

The outside-vehicle information detection unit 12030 detects information about the outside of the vehicle including the vehicle control system 12000. For example, a distance measurement device 12031 is connected to the outside-vehicle information detection unit 12030. The distance measurement device 12031 includes the distance measurement device 1000 described above. The outside-vehicle information detection unit 12030 causes the distance measurement device 12031 to measure a distance to an object (subject S) outside the vehicle, and acquires distance data acquired by the measurement. The outside-vehicle information detection unit 12030 may perform object detection processing of a person, a car, an obstacle, a sign, or the like on the basis of the acquired distance data.

The in-vehicle information detection unit 12040 detects information about the inside of the vehicle. The in-vehicle information detection unit 12040 is, for example, connected with a driver state detection section 12041 that detects the state of a driver. The driver state detection section 12041, for example, includes a camera that images the driver. On the basis of detection information input from the driver state detection section 12041, the in-vehicle information detection unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detection unit 12030 or the in-vehicle information detection unit 12040, and output a control command to the drive system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

Furthermore, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detection unit 12030 or the in-vehicle information detection unit 12040.

Furthermore, the microcomputer 12051 can output a control command to the body system control unit 12020 on the basis of the information about the outside of the vehicle acquired by the outside-vehicle information detection unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detection unit 12030.

The sound/image output section 12052 transmits an output signal of at least one of a sound and an image to an output device capable of visually or auditorily notifying information to an occupant of the vehicle or the outside of the vehicle. In the example of FIG. 51, an audio speaker 12061, a display section 12062, and an instrument panel 12063 are illustrated as the output device. The display section 12062 may, for example, include at least one of an on-board display and a head-up display.

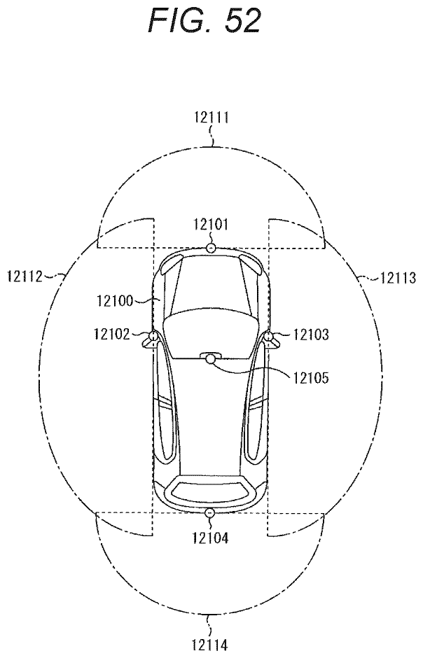

FIG. 52 is a diagram illustrating an example of an installation position of the distance measurement device 12031.

In FIG. 52, a vehicle 12100 includes distance measurement devices 12101, 12102, 12103, 12104, and 12105 as the distance measurement device 12031.

For example, the distance measurement devices 12101, 12102, 12103, 12104, and 12105 are provided at positions such as a front nose, sideview mirrors, a rear bumper, a back door, an upper portion of a windshield in a vehicle interior, and the like of the vehicle 12100. The distance measurement device 12101 provided at the front nose and the distance measurement device 12105 provided at the upper portion of the windshield in the vehicle interior mainly acquire data of the front side of the vehicle 12100. The distance measurement devices 12102 and 12103 provided at the sideview mirrors mainly acquire data of the sides of the vehicle 12100. The distance measurement device 12104 provided at the rear bumper or the back door mainly acquires data of the rear side of the vehicle 12100. The data of the front side acquired by the distance measurement devices 12101 and 12105 is mainly used to detect a preceding vehicle, a pedestrian, an obstacle, a traffic light, a traffic sign, or the like.

Note that FIG. 52 illustrates an example of detection ranges of the distance measurement devices 12101 to 12104. A detection range 12111 indicates a detection range of the distance measurement device 12101 provided at the front nose, detection ranges 12112 and 12113 indicate detection ranges of the distance measurement devices 12102 and 12103 provided at the sideview mirrors, respectively, and a detection range 12114 indicates a detection range of the distance measurement device 12104 provided at the rear bumper or the back door.

For example, the microcomputer 12051 obtains a distance to each three-dimensional object within the detection ranges 12111 to 12114 and a temporal change in the distance (relative speed with respect to the vehicle 12100) on the basis of the distance data obtained from the distance measurement devices 12101 to 12104, thereby extracting particularly a nearest three-dimensional object present on a traveling path of the vehicle 12100, which travels in substantially the same direction as the vehicle 12100 at a predetermined speed (for example, equal to or more than 0 km/h), as a preceding vehicle. Moreover, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data regarding three-dimensional objects into two-wheeled vehicles, standard-sized vehicles, large-sized vehicles, pedestrians, and other three-dimensional objects such as utility poles, extract the three-dimensional object data, and use the three-dimensional object data for automatic avoidance of obstacles, on the basis of the distance data obtained from the distance measurement devices 12101 to 12104. For example, the microcomputer 12051 identifies obstacles around the vehicle 12100 as obstacles that the driver of the vehicle 12100 can recognize visually and obstacles that are difficult for the driver of the vehicle to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the drive system control unit 12010. The microcomputer 12051 can thereby assist in driving to avoid collision.

An example of the moving body control system to which the technology according to the present disclosure can be applied has been described above. The technology according to the present disclosure may be applied to the distance measurement device 12031 among the configurations described above.

Furthermore, the present technology may also adopt the following configurations.

(1) A surface emitting element including:
a first structure including a substrate; and
a second structure provided on the first structure and including a light emitting layer including a light emitting region,
in which the first structure includes a low resistance region that is a region in contact with the second structure and has lower resistance than other regions, and
the low resistance region is provided at a position deviated from at least a central portion of the light emitting region in a plan view.

(2) The surface emitting element according to (1), in which the low resistance region has a higher impurity concentration than the other regions.

(3) The surface emitting element according to (1) or (2), in which the second structure includes a plurality of element configuration parts arranged in an in-plane direction on the first structure via an insulating region or a high resistance region, and the low resistance region is in contact with at least one element configuration part of the plurality of element configuration parts.

(4) The surface emitting element according to (3), in which the low resistance region is in contact with at least two element configuration parts of the plurality of element configuration parts.

(5) The surface emitting element according to (3) or (4), in which the plurality of element configuration parts includes at least one first element configuration part, and at least one second element configuration part, a first electrode is provided on the at least one first element configuration part, and a second electrode is provided on the at least one second element configuration part.

(6) The surface emitting element according to (5), in which the first element configuration part includes a light emitting element configuration part including the light emitting region, and the second element configuration part includes a dummy element configuration part not including the light emitting region.

(7) The surface emitting element according to (5) or (6), in which the low resistance region is in contact with the second element configuration part, and at least the second element configuration part is provided with another low resistance region connecting the low resistance region and the second electrode.

(8) The surface emitting element according to any one of (5) to (7), in which the low resistance region is in contact with the first element configuration part.

(9) The surface emitting element according to any one of (5) to (8), in which the low resistance region is not in contact with a central portion of the first element configuration part but in contact with a peripheral portion.

(10) The surface emitting element according to (5) or (6), in which the second electrode is provided on the second element configuration part via an insulating film, the low resistance region is in contact with at least the first element configuration part and a third electrode disposed between the first and second element configuration parts, and a wiring connecting the third electrode and the second electrode is provided on at least a side surface of the second element configuration part via an insulating film.

(11) The surface emitting element according to (5) or (6), in which the at least one second element configuration part includes a plurality of dummy element configuration parts including first and second dummy element configuration parts, the second electrode is provided on the first dummy element configuration part, another second electrode is provided on the second dummy element configuration part via an insulating film, the low resistance region is in contact with the light emitting element configuration part and/or the first dummy element configuration part, the first dummy element configuration part includes another low resistance region connecting the low resistance region and the second electrode, and a wiring connecting the first electrode and the another second electrode is provided along the light emitting element configuration part and the second dummy element configuration part via an insulating film.

(12) The surface emitting element according to any one of (3) to (11), in which the plurality of element configuration parts includes a plurality of light emitting element configuration parts, and the low resistance region is in contact with at least two of the plurality of light emitting element configuration parts.

(13) The surface emitting element according to any one of (3) to (12), in which at least one of the plurality of element configuration parts has a mesa shape.

(14) The surface emitting element according to (1), in which the second structure includes a light emitting element configuration part including the light emitting region, an electrode separated from the light emitting element configuration part in an in-plane direction and/or a stacking direction is provided in the first structure, and the low resistance region is in contact with the light emitting element configuration part and/or the electrode.

(15) The surface emitting element according to (14), in which the light emitting element configuration part has a mesa shape, another electrode is provided on the light emitting element configuration part, and the electrode is disposed on the first structure to be spaced apart from the light emitting element configuration part in the in-plane direction.

(16) The surface emitting element according to (14), in which the light emitting element configuration part has a mesa shape, another electrode is provided on the light emitting element configuration part, and the electrode is provided on a side surface of the light emitting element configuration part on the first structure via an insulating film.

(17) The surface emitting element according to (14), in which the light emitting element configuration part has a mesa shape, another electrode is provided on the light emitting element configuration part, the electrode is disposed on the first structure to be spaced apart from the light emitting element configuration part in the in-plane direction, yet another electrode is provided on a side surface of the light emitting element configuration part on a side different from a side of the electrode via an insulating film on the first structure, and a wiring connecting the another electrode and the yet another electrode is provided along the light emitting element configuration part.

(18) The surface emitting element according to any one of (1) to (17), in which the second structure includes a reflecting mirror on a side of the substrate of the light emitting layer and/or a side opposite to the side of the substrate.

(19) The surface emitting element according to any one of (1) to (18), in which light is emitted to a side of the first structure.

(20) The surface emitting element according to any one of (1) to (19), in which light is emitted to a side of the second structure.

### REFERENCE SIGNS LIST

10, 10-1, 10-2, 20, 20-1, 20-2, 30, 30-1, 30-2, 40, 40-1, 40-2, 50, 50-1, 50-2, 60, 60-1, 60-2, 70, 70-1, 70-2, 80, 80-1, 80-2, 90, 90-1, 90-2, 100, 100-1, 100-2, 110-1˜110-7, 120-1˜120-3, 130-1˜130-3, 140-1, 150-1 Surface emitting element
101 Substrate
101a, 102a Low resistance region
101b, 102b1 Other regions
103 Light emitting layer
103a Light emitting region
102A First reflecting mirror (reflecting mirror)
104A Second reflecting mirror (reflecting mirror)
105 Another low resistance region
106 First electrode
107 Second electrode
111 Intermediate electrode (third electrode)
112, 113, 114, 116 Wiring
115 Ion implantation region (high resistance region)
ST1 First structure
ST2 Second structure
M1 First mesa (element configuration part, light emitting element configuration part)
M2 Second mesa (element configuration part, dummy element configuration part)

1. A surface emitting element comprising:
a first structure including a substrate; and
a second structure provided on the first structure and including a light emitting layer including a light emitting region,
wherein the first structure includes a low resistance region that is a region in contact with the second structure and has lower resistance than other regions, and
the low resistance region is provided at a position deviated from at least a central portion of the light emitting region in a plan view.

2. The surface emitting element according to claim 1, wherein the low resistance region has a higher impurity concentration than the other regions.

3. The surface emitting element according to claim 1, wherein the second structure includes a plurality of element configuration parts arranged in an in-plane direction on the first structure via an insulating region or a high resistance region, and
the low resistance region is in contact with at least one element configuration part of the plurality of element configuration parts.

4. The surface emitting element according to claim 3, wherein the low resistance region is in contact with at least two element configuration parts of the plurality of element configuration parts.

5. The surface emitting element according to claim 3, wherein the plurality of element configuration parts includes
at least one first element configuration part, and
at least one second element configuration part,
a first electrode is provided on the at least one first element configuration part, and
a second electrode is provided on the at least one second element configuration part.

6. The surface emitting element according to claim 5, wherein the first element configuration part includes a light emitting element configuration part including the light emitting region, and
the second element configuration part includes a dummy element configuration part not including the light emitting region.

7. The surface emitting element according to claim 6, wherein the low resistance region is in contact with the second element configuration part, and
at least the second element configuration part is provided with another low resistance region connecting the low resistance region and the second electrode.

8. The surface emitting element according to claim 7, wherein the low resistance region is in contact with the first element configuration part.

9. The surface emitting element according to claim 6, wherein the low resistance region is not in contact with a central portion of the first element configuration part but in contact with a peripheral portion.

10. The surface emitting element according to claim 6, wherein the second electrode is provided on the second element configuration part via an insulating film,
the low resistance region is in contact with at least the first element configuration part and a third electrode disposed between the first and second element configuration parts, and
a wiring connecting the third electrode and the second electrode is provided on at least a side surface of the second element configuration part via an insulating film.

11. The surface emitting element according to claim 6, wherein the at least one second element configuration part includes a plurality of dummy element configuration parts including first and second dummy element configuration parts,
the second electrode is provided on the first dummy element configuration part,
another second electrode is provided on the second dummy element configuration part via an insulating film,
the low resistance region is in contact with the light emitting element configuration part and/or the first dummy element configuration part,
another low resistance region connecting the low resistance region and the second electrode is provided in at least the first dummy element configuration part, and
a wiring connecting the first electrode and the another second electrode is provided along the light emitting element configuration part and the second dummy element configuration part via an insulating film.

12. The surface emitting element according to claim 3, wherein the plurality of element configuration parts includes a plurality of light emitting element configuration parts, and
the low resistance region is in contact with at least two of the plurality of light emitting element configuration parts.

13. The surface emitting element according to claim 3, wherein at least one of the plurality of element configuration parts has a mesa shape.

14. The surface emitting element according to claim 1, wherein the second structure includes a light emitting element configuration part including the light emitting region,
an electrode separated from the light emitting element configuration part in an in-plane direction and/or a stacking direction is provided in the first structure, and
the low resistance region is in contact with the light emitting element configuration part and/or the electrode.

15. The surface emitting element according to claim 14, wherein the light emitting element configuration part has a mesa shape,
another electrode is provided on the light emitting element configuration part, and
the electrode is disposed on the first structure to be spaced apart from the light emitting element configuration part in the in-plane direction.

16. The surface emitting element according to claim 14, wherein the light emitting element configuration part has a mesa shape,
another electrode is provided on the light emitting element configuration part, and
the electrode is provided on a side surface of the light emitting element configuration part on the first structure via an insulating film.

17. The surface emitting element according to claim 14, wherein the light emitting element configuration part has a mesa shape,
another electrode is provided on the light emitting element configuration part,
the electrode is disposed on the first structure to be spaced apart from the light emitting element configuration part in the in-plane direction,
yet another electrode is provided on a side surface of the light emitting element configuration part on a side different from a side of the electrode via an insulating film on the first structure, and
a wiring connecting the another electrode and the yet another electrode is provided along the light emitting element configuration part.

18. The surface emitting element according to claim 1, wherein the second structure includes a reflecting mirror on a side of the substrate of the light emitting layer and/or a side opposite to the side of the substrate.

19. The surface emitting element according to claim 1, wherein light is emitted to a side of the first structure.

20. The surface emitting element according to claim 1, wherein light is emitted to a side of the second structure.
